(19) United States
(12) Patent Application Publication
(10) Pub. No.: US 2017/0301766 A1
(43) Pub. Date: Oct. 19, 2017

(54) COMPOUND SEMICONDUCTOR FIELD EFFECT TRANSISTOR

(71) Applicant: SHARP KABUSHIKI KAISHA, Sakai City, Osaka (JP)

(72) Inventor: Hisao ICHIJOH, Sakai City, Osaka (JP)

(73) Assignee: SHARP KABUSHIKI KAISHA, Sakai City, Osaka (JP)

(21) Appl. No.: 15/511,601

(22) PCT Filed: Jun. 10, 2015
(86) PCT No.: PCT/JP2015/066782

§ 371 Date: Mar. 15, 2017

(30) Foreign Application Priority Data
Sep. 17, 2014 (JP) 2014-189112

(51) Int. Cl. H01L 29/423; H01L 29/20; H01L 29/205; H01L 29/778

(52) U.S. Cl. CPC H01L 29/42316; H01L 29/7787; H01L 29/2003; H01L 29/205

(57) ABSTRACT

A connection portion (88) in a gate electrode connecting wire (85), which connects the gate electrode connecting wire (85) defining a substantially rectangular region (30) having a long side and a short side encompassing all the gate electrode (13) and a gate electrode pad (87), is positioned on the long side of the substantially rectangular region (30) in plan view.

### TECHNICAL FIELD

The present invention relates to a compound semiconductor field effect transistor such as a heterojunction field effect transistor (HFET).

### BACKGROUND ART

At present, metal oxide semiconductor field effect transistors (MOSFETs) formed of silicon (Si) and insulated gate bipolar transistors (IGBTs) are widely used as semiconductor power devices. However, these Si devices are approaching their performance limits due to physical properties of their materials, and lowering the on-resistance and increasing the speed in addition to securing a high breakdown voltage will be more difficult in the future.

Here, the use of compound semiconductors represented by gallium nitride (GaN) and silicon carbide (SiC) is increasing expectations for realizing low loss devices that surpass the limit of Si power devices.

In particular, GaN has material physical properties such that, compared with Si, a band gap is about 3 times as large, the breakdown field is larger by one digit, and the saturated electron velocity is larger, thus GaN-based heterojunction field effect transistors (HFETs) are expected to have significantly higher breakdown voltage/lowered resistances and higher speeds than Si devices.

However, GaN-based HFETs are generally susceptible to the influence of parasitic inductance and parasitic capacitance on a circuit since voltage change and current change in an actual circuit are extremely large due to the high speed, and there are problems such as destabilization or destruction during circuit operation.

In the related art, PTL 1 (Japanese Unexamined Patent Application Publication No. 2010-186925) describes GaN-based field effect transistors. As illustrated in FIG. 14, a field effect transistor is provided with a drain electrode 214, a source electrode 212, a gate electrode 216, a gate electrode pad 225, a gate electrode connecting wire 227, and a resistance element 231. The gate electrode connecting wire 227 is formed of a finger connection portion 228 and a pad connection portion 229. The gate electrode 216 is provided in the shape of a plurality of fingers, and the gate electrode connecting wire 227 connected to one end side of each gate electrode 216 is connected to the gate electrode pad 225 via the resistance element 231. When the field effect transistor is used as a switching device, the occurrence of an unstable state such as ringing or oscillation during circuit operation is suppressed by the resistance element 231.

In addition, in the related art, PTL 2 (Japanese Examined Patent Application Publication No. 6-87505) describes a field effect transistor. As illustrated in FIG. 15, the field effect transistor is provided with a plurality of gate electrodes 451 formed in a finger shape, a gate lead-out electrode portion 452 connected to one end side of each gate electrode 451, and a gate electrode pad 453 connected to the gate lead-out electrode portion 452. A stabilization resistance 454 is inserted into the gate lead-out electrode portion 452 side of each gate electrode 451. The stabilization resistance 454 enables a uniform operation of the field effect transistor and suppresses the occurrence of unstable states at the time of circuit operation.

### CITATION LIST

### Patent Literature

PTL 1: Japanese Unexamined Patent Application Publication No. 2010-186925
PTL 2: Japanese Examined Patent Application Publication No. 6-87505

### SUMMARY OF INVENTION

### Technical Problem

However, in the field effect transistors of PTL 1 and PTL 2, the connection positions of the gate electrodes 216 and 451 and the gate electrode pads 225 and 453 are not defined in consideration of signal delay and uniform operation. The gate electrode pads 225 and 453 are connected only to one end side of the gate electrodes 216 and 451 and thus a signal delay occurs in the transistors and uniform operation is not possible when the field effect transistors are used as a switching device, which is a problem.

In addition, depending on the usage environment, a load short-circuit resistance is sometimes required; however, when the load is short-circuited, the stress of high voltage and high current state is applied to the field effect transistor and, if there is a non-uniform operation in the transistor, there is a problem in that a hot spot is generated which decreases the short-circuit resistance.

Detailed description will be given below of a non-uniform operation of the field effect transistor by referring to FIG. 1, FIGS. 3(a), 3(b), and 3(c), FIGS. 4(a) and 4(b), and FIGS. 5(a), 5(b), 5(c), and 5(d).

Note that, FIG. 1, FIGS. 3(a), 3(b), and 3(c), FIGS. 4(a) and 4(b), and FIGS. 5(a), 5(b), 5(c), and 5(d) are diagrams for describing matters to be addressed by the present invention in detail, and not diagrams illustrating the related art. In particular, FIG. 1 is a plan view of a first embodiment of the present invention and FIG. 1 is also used to address the matters in order to reduce the number of drawings.

First, FIG. 1 illustrates a schematic plan view of a compound semiconductor field effect transistor.

As illustrated in FIG. 1, this compound semiconductor field effect transistor has a drain electrode 11, a source electrode 12, and a gate electrode 13, and the drain electrode 11 and the source electrode 12 extend in a finger shape in a first direction and a plurality of the drain electrodes 11 and the source electrodes 12 are arranged alternately substantially parallel to each other at predetermined intervals in a second direction substantially orthogonal to the first direction.

In addition, the gate electrode 13 extends in the first direction between the finger-shaped drain electrode 11 and the finger-shaped source electrode 12 in plan view, and extends so as to surround the periphery of the drain electrode 11 in a loop-shape. The gate electrode 13 has an interval determined in advance with respect to the drain electrode 11 and the source electrode 12.

A substantially rectangular loop-shaped gate electrode connecting wire 15 defines a substantially rectangular region 20 having long sides and short sides encompassing all the gate electrodes 13.

Both ends of the gate electrode 13 in the first direction are respectively connected to the gate electrode connecting wire 15, and a connection portion 18 in the gate electrode connecting wire 15 is connected to a gate electrode pad 17 via a gate electrode pad connecting wire 16. The connection portion 18 is positioned on a long side of the rectangular region 20. The gate electrode pad 17 is arranged on one end side of the gate electrode 13 in the first direction.

The gate electrode connecting wire 15 and the gate electrode pad connecting wire 16 are, for example, formed of a Ti/AlCu/TiN electrode or the like in which a Ti layer, an AlCu layer, and a TiN layer are laminated in order.

In addition, the drain electrode 11, the gate electrode 13, and a part of the gate electrode connecting wire 15 form a rectangular gate finger 14 surrounded by a broken line in FIG. 1.

In order to reduce the on-resistance in a case where it is desired that a large current flow through the compound semiconductor field effect transistor, for example, a plurality of gate fingers 14 are arranged in the second direction and one gate finger group 14a is formed of the plurality of gate fingers 14 and the rectangular loop-shaped gate electrode connecting wire 15 surrounding the plurality of gate fingers 14.

Next, description will be given of an equivalent circuit in the case where the compound semiconductor field effect transistor illustrated in FIG. 1 performs a switching operation and the operation state thereof with reference to FIGS. 3(a), 3(b), and 3(c), and FIGS. 4(a) and 4(b).

FIG. 3(a) is an equivalent circuit of the compound semiconductor field effect transistor illustrated in FIG. 1, the gate electrode pad 17 in FIG. 1 corresponds to a gate terminal 37 in FIG. 3(a), a drain electrode pad and a source electrode pad (not shown) in FIG. 1 correspond to a drain terminal 38 and a source terminal 39 in FIG. 3(a). In addition, as illustrated in FIG. 3(a), an equivalent resistance component from the drain electrode pad (not shown) in FIG. 1 to the drain electrode 11 is referred to as a drain resistance 331, an equivalent resistance component from a source electrode pad (not shown) in FIG. 1 to the source electrode 12 is referred to as a source resistance 332, and an equivalent resistance component from the gate electrode pad 17 in FIG. 1 to the gate electrode 13 is referred to as a gate resistance 333. In addition, the capacitance between the drain electrode 11 and the gate electrode 13 in FIG. 1 is set to be equivalent to a gate-drain capacitance 34 (FIG. 3(a)). The resistance value of the drain resistance 331 is Rd, the resistance value of the source resistance 332 is Rs, the resistance value of the gate resistance 333 is Rg, and the capacitance value of the gate-drain capacitance 34 is Cgd. Note that, below, for convenience, the gate-drain capacitance 34 may be represented by the capacitance value Cgd in some cases.

FIG. 3(b) is an equivalent circuit in a case where the compound semiconductor field effect transistor illustrated in FIG. 1 performs a switching operation. As illustrated in FIG. 3(b), in the compound semiconductor field effect transistor illustrated in FIG. 3(a), the source terminal 39 is fixed at the GND potential, the drain terminal 38 is connected to a first power source 36a through a load 35, and the gate terminal 37 is connected to a second power source 36b.

Generally, in a case where the field effect transistor performs a switching operation, a pulsed gate signal as illustrated in FIG. 3(c) is input from the second power source 36b (refer to FIG. 3(b)) to the gate terminal 37. When a signal changing from Low (low level) to High (high level) is input to the gate terminal 37 and the potential of a gate electrode 33 is the threshold voltage or more of the transistor, the drain voltage Vds begins to decrease (turn-ON), the potential of a drain electrode 31 becomes Low, and the transistor is turned on. In addition, when a High to Low signal is input to the gate terminal 37, the drain voltage Vds begins to increase (turn-OFF), the drain voltage Vds becomes High, and the transistor is turned off. In this manner, the field effect transistor repeats the ON state and the OFF state according to the gate signal and, due to this, the drain voltage Vds quickly changes in a short time such as turn-ON and turn-OFF. Here, the inclination of the changes of the drain voltage Vds is expressed as dV/dt and is expressed as (dV/dt)on at turn-ON and is expressed as (dV/dt)off at turn-OFF.

As illustrated in FIG. 4(a), at turn-ON, when a High signal is input to the gate terminal 37 (arrow A), since the potential of the drain electrode 31 quickly decreases (arrow B) thereafter, a current indicated by an arrow C flows from the gate electrode 33 toward the drain electrode 31 via the gate-drain capacitance Cgd. The current indicated by the arrow C is expressed as follows.

I1=Cgd×(dV/dt)on

Since the current I1 flows through the gate resistance 333, the potential of the gate electrode 33 decreases as follows. Assuming that the voltage decrease amount of the gate electrode 33 is ΔV1:

ΔV1=I1×Rg=Rg×Cgd×(dV/dt)on Equation (1)

That is, at the time of turn-ON in the case of increasing the gate voltage, since the current through the gate-drain capacitance Cgd flows from the gate electrode 33 toward the drain electrode 31 due to the sharp decrease in the drain voltage Vds, the gate voltage acts inversely in a decreasing direction, ringing or the like occurs, and the gate voltage and the drain voltage become unstable.

In particular, when the voltage decrease amount ΔV is large and the potential of the gate electrode 33 is a threshold voltage or less, the compound semiconductor field effect transistor is instantaneously turned off, oscillation or the like occurs, and it is not possible to realize a stable operation, in which case destruction may result.

On the other hand, as illustrated in FIG. 4(b), at turn-OFF, when a Low signal is input to the gate terminal 37 (arrow A), since the potential of the drain electrode 31 quickly increases (arrow B), the current indicated by the arrow C flows from the drain electrode 31 toward the gate electrode 33 through the gate-drain capacitance Cgd. The current indicated by the arrow C is expressed as follows.

I2=Cgd×(dV/dt)off

Since the current I2 flows through the gate resistance 333, the potential of the gate electrode 33 increases as follows. Assuming that the voltage increase amount of the gate electrode 33 is ΔV2:

ΔV2=I2×Rg×Rg×Cgd×(dV/dt)off Equation (2)

That is, at turn-OFF in a case where the gate voltage is Down (falling), since current through the gate-drain capacitance Cgd flows from the drain electrode 31 toward the gate electrode 33 due to the sharp increase in the drain voltage Vds, the gate voltage acts inversely in an increasing direction and ringing or the like occurs such that the gate voltage and the drain voltage become unstable.

In particular, when the voltage increase amount ΔV is large and the potential of the gate electrode 33 is the threshold voltage or more, the transistor is instantaneously turned on, oscillation or the like occurs, and it is not possible to realize a stable operation, in which case destruction may result.

In general, the capacitance value Cgd of the gate-drain capacitance 34 shown in the equations (1) and (2) has a drain voltage dependency, and when the drain voltage Vds is a low voltage, the capacitance value Cgd is extremely high at, for example, about 10 times compared to that when the drain voltage Vds is a high voltage. Accordingly, from equations (1) and (2), the voltage change amount ΔV during switching is larger when the drain voltage is a low voltage than a high voltage, and the operation of the field effect transistor may easily become unstable when the drain voltage is a low voltage.

Next, description will be given with reference to FIGS. 5(a), 5(b), 5(c), and 5(d) of the extent to which the voltage changes occur in one gate finger during the switching operation of the compound semiconductor field effect transistor, when the drain voltage is a low voltage.

FIG. 5(a) illustrates an example of a compound semiconductor field effect transistor having, for example, approximately 100 gate fingers.

As illustrated in FIG. 5(a), a drain electrode 51, a source electrode 52, and a gate electrode 53 extend in the first direction, and the gate electrode 53 has a substantially rectangular loop-shape surrounding the drain electrode 51. The drain electrode 51, the source electrode 52, and the gate electrode 53 are arranged at regular intervals in a second direction orthogonal to the first direction. Both ends of the gate electrode 53 in the first direction are connected to a long side portion of a substantially rectangular loop-shaped gate electrode connecting wire 55 having long sides and short sides. A substantially rectangular gate finger 54 is formed of the drain electrode 51, the gate electrode 53, and a part of the gate electrode connecting wire 55 in plan view.

As illustrated in FIG. 5(b), the extending distance (referred to below as the gate finger length) of the gate finger 54 in the first direction is 2,000 μm or less, for example, 1,600 μm, and the width of the gate electrode 53 in the second direction is, for example, 5 μm.

FIG. 5(c) is an equivalent circuit of the gate finger 54 illustrated in FIG. 5(b), and the gate resistance 553 is an equivalent resistance from a gate terminal 57 to the gate electrode 53. As illustrated in FIG. 5(c), the resistance value of a drain resistance 551 is Rd, the resistance value of a source resistance 552 is Rs, the resistance value of a gate resistance 553 is Rg, and the capacitance value of a gate-drain capacitance 554 is Cgd. Note that, for convenience, the gate-drain capacitance 554 may be represented by the capacitance value Cgd.

As illustrated in FIGS. 5(b) and 5(d), the gate finger 54 is represented by a matrix of the resistance rg and the capacitance cgd per unit length of the gate finger 54 in the first direction, and it is possible to represent the gate finger 54 as a distributed constant. The resistance value of the resistance rg represented as this distributed constant is also represented by rg, and the capacitance value of the capacitance cgd is also represented by cgd.

The gate-drain capacitance 554 illustrated in FIG. 5(c) is an equivalent capacitance between the gate electrode 53 and the drain electrode 51. As described above, the voltage change amount at turn-OFF is represented by equation (2).

At this time, the (dV/dt)off of the GaN-based compound semiconductor field effect transistor is extremely large, for example, approximately 100 V/ns in comparison with that of a Si-based device. In addition, the gate-drain capacitance Cgd where the drain voltage is in the low voltage region is, for example, approximately 50 pF, and approximately 50 pF/100=0.5 pF per gate finger. In addition, as illustrated in FIG. 5(d), the resistance value Rg of the gate resistance 553 illustrated in FIG. 5(c) is determined as a distributed constant by the capacitance cgd and the resistance rg and, when the sheet resistance of the gate electrode 53 is set to 5Ω/□, the resistance value Rg is represented as follows.

Rg(1/3)×(5 Ω/□×1,600 μm/5 μm×1/8)=67Ω

Accordingly, as shown in Equation (2), when the voltage increase amount is ΔV2,

ΔV2=Rg×Cgd×(dV/dt)off≅67Ω×0.5 pF×100 V/ns=3.4 V.

That is, in a case where a GaN-based compound semiconductor field effect transistor performs a switching operation, when the drain voltage is a low voltage, gate voltage changes of approximately 3.4 V occur within one gate finger.

Generally, the threshold voltage of a GaN-based compound semiconductor field effect transistor is often designed to be 1.5 to 4 V and the voltage increase amount ΔV2 is a value equal thereto or higher, and there are problems such as ringing or oscillation occurring and the transistor operation becoming unstable.

In addition, in a case of comparing the GaN-based compound semiconductor field effect transistor and the Si-based field effect transistor having substantially the same rated current, rated voltage, and on-resistance, regarding the gate charge amount Qg correlated with the turn-ON time and the turn-OFF time, the GaN-based compound semiconductor field effect transistor is, for example, 5 to 7 nC, while the Si-based field effect transistor is approximately 10 times as large at 50 to 70 nC, dV/dt in the GaN-based compound semiconductor field effect transistor is approximately 10 times that of the Si-based field effect transistor, and it is necessary to design a transistor with special attention with respect to non-uniform operations in the transistor. Naturally the same attention is required for similar high-speed devices other than GaN-based compound semiconductor field effect transistors.

Accordingly, in the GaN-based compound semiconductor field effect transistor of the related art described in PTL 1 and PTL 2, only one end of the gate electrode is connected to the gate electrode connecting wire, and in PTL 1, only one end of a linear gate electrode connecting wire is connected to a gate electrode pad, thus gate voltage changes in, for example, GaN-based compound semiconductor field effect transistors become large, signal delay occurs, and, in addition, uniform operation is not performed, it is not possible to sufficiently suppress ringing and oscillation, it is not possible to realize a stable operation of the compound semiconductor field effect transistor, and, furthermore, there is a problem in that the short-circuit resistance at the time of a load short-circuit is low.

Therefore, it is an object of the present invention to provide a compound semiconductor field effect transistor with a reduced signal delay, carrying out a uniform operation, able to sufficiently suppress ringing and oscillation, and able to realize a stable operation, and furthermore able to secure a high short-circuit resistance.

### Solution to Problem

In order to solve the above problems, a compound semiconductor field effect transistor of the present invention includes a drain electrode formed on a semiconductor layer so as to extend in a first direction, a source electrode formed on the semiconductor layer so as to extend in the first direction and to be separated from the drain electrode with an interval determined in advance in a second direction intersecting the first direction, a gate electrode extending in the first direction and formed between the drain electrode and the source electrode in plan view, a gate electrode connecting wire that has opposing portions to which both ends of the gate electrode in the first direction are connected and that defines a substantially rectangular region having a long side and a short side encompassing all the gate electrode in plan view, an insulating layer formed on the semiconductor layer so as to cover the gate electrode, and a gate electrode pad formed on the insulating layer and connected to the gate electrode connecting wire, in which a plurality of gate fingers each of which is arranged with the source electrode and includes the drain electrode, the gate electrode, and a part of the gate electrode connecting wire, a gate finger group including a plurality of the gate fingers is formed, and a connection portion in the gate electrode connecting wire which connects the gate electrode connecting wire and the gate electrode pad is positioned on the long side of the substantially rectangular region.

In one embodiment, each finger group of a plurality of gate finger groups is surrounded by the gate electrode connecting wire, and in each of the gate finger groups, a connection portion in the gate electrode connecting wire which connects the gate electrode connecting wire and the gate electrode pad is positioned at a midpoint of a portion of the long side in the gate electrode connecting wire belonging to the gate finger group.

In one embodiment, the number of the gate finger groups is 3, connection portions each positioned at a midpoint of a portion of the long side in the gate electrode connecting wire belonging to adjacent gate finger groups are interconnected with two first gate electrode pad connecting wires, and a connection point of the two first gate electrode pad connecting wires is connected to a gate electrode pad.

In one embodiment, the number of the gate finger groups is N (N is a natural number and N≧3), connection portions each positioned at a midpoint of a portion of the long side in the gate electrode connecting wire belonging to adjacent gate finger groups are interconnected with (N−1) first gate electrode pad connecting wires, here, m=a natural number of 1 to (N−2), midpoints of an m-th gate electrode pad connecting wire of (N−m) adjacent wires are connected by an (m+1)-th gate electrode pad connecting wire of (N−(m+1)) wires, and a midpoint of one (N−1)-th gate electrode pad connecting wire is connected to the gate electrode pad.

In one embodiment, the gate electrode pad connecting wire is parallel to the first direction, and a plurality of gate finger groups are arranged in the second direction.

In one embodiment, a length of the gate finger extending in the first direction is 2,000 μm or less. In addition, according to another aspect of the present invention, a compound semiconductor field effect transistor of the present invention includes a drain electrode formed on a semiconductor layer so as to extend in a first direction, a source electrode formed on the semiconductor layer so as to extend in the first direction and to be separated from the drain electrode with an interval determined in advance in a second direction intersecting the first direction, a gate electrode extending in the first direction and formed between the drain electrode and the source electrode in plan view, a gate electrode connecting wire that has opposing portions to which both ends of the gate electrode in the first direction are connected and that defines a substantially rectangular region having a long side and a short side encompassing all the gate electrode in plan view, an insulating layer formed on the semiconductor layer so as to cover the gate electrode, and a gate electrode pad formed on the insulating layer and connected to the gate electrode connecting wire, in which a plurality of gate fingers each of which is arranged with the source electrode and includes the drain electrode, the gate electrode, and a part of the gate electrode connecting wire, a gate finger group including a plurality of the gate fingers is formed, a connection portion in the gate electrode connecting wire which connects the gate electrode connecting wire and the gate electrode pad is positioned on the short side of the substantially rectangular region, each gate finger group of a plurality of gate finger groups is surrounded by the gate electrode connecting wire, and in each of the gate finger groups, a connection portion in the gate electrode connecting wire which connects the gate electrode connecting wire and the gate electrode pad is positioned at a midpoint of a portion of the short side in the gate electrode connecting wire belonging to the gate finger group, connection portions each positioned at the midpoint of the portion of the short side in the gate electrode connecting wire belonging to adjacent gate finger groups are interconnected with a gate electrode pad connecting wire, and a midpoint of the first gate electrode pad connecting wire is directly or indirectly connected to the gate electrode pad.

In one embodiment, the gate electrode pad connecting wire is parallel to the second direction, and a plurality of gate finger groups are arranged in the first direction.

### Advantageous Effects of Invention

According to the compound semiconductor field effect transistor of the present invention, it is possible to reduce the signal delay, to realize a stable uniform operation, to sufficiently suppress ringing and oscillation, and to secure a high short-circuit resistance.

### BRIEF DESCRIPTION OF DRAWINGS

FIG. 1 is a schematic plan view of a main portion of a compound semiconductor field effect transistor of a first embodiment of the present invention.

FIG. 2 is a sectional view illustrating a section taken along line A-A in FIG. 1.

FIG. 3(a) is an equivalent circuit diagram of the compound semiconductor field effect transistor illustrated in FIG. 1.

FIG. 3(b) is an equivalent circuit diagram in a case of the compound semiconductor field effect transistor illustrated in FIG. 1 performing a switching operation.

FIG. 3(c) is a diagram illustrating an operation waveform in a case where the compound semiconductor field effect transistor illustrated in FIG. 1 performs a switching operation.

FIG. 4(a) is a schematic diagram illustrating an operation state at turn-ON in a case where the compound semiconductor field effect transistor illustrated in FIG. 1 performs a switching operation.

FIG. 4(b) is a schematic diagram illustrating an operation state at turn-OFF in a case of the compound semiconductor field effect transistor illustrated in FIG. 1 performing a switching operation.

FIG. 5(a) is a schematic plan view illustrating an example of a compound semiconductor field effect transistor having approximately 100 gate fingers.

FIG. 5(b) is a schematic plan view of gate fingers of the compound semiconductor field effect transistor illustrated in FIG. 5(a).

FIG. 5(c) illustrates an equivalent circuit the gate finger illustrated in FIG. 5(b).

FIG. 5(d) is an equivalent circuit diagram in a case where the resistance and capacitance per unit length of the gate finger in a first direction are rg and cgd, respectively.

FIG. 6(a) is a schematic plan view of a compound semiconductor field effect transistor in a case where gate finger groups are arranged in the first direction.

FIG. 6(b) is a schematic plan view of the compound semiconductor field, effect transistor in a case where gate finger groups are arranged in a second direction.

FIG. 7(a) is a schematic plan view which represents the compound semiconductor field effect transistor in FIG. 6(a), focusing on the gate finger groups surrounded by a gate electrode connecting wire.

FIG. 7(b) is a schematic plan view which represents the compound semiconductor field effect transistor in FIG. 6(b), focusing on the gate finger groups surrounded by the gate electrode connecting wire.

FIG. 8(a) a schematic plan view of a compound semiconductor field effect transistor of a comparative example having a connection portion with a gate electrode pad connecting wire on the short side of a rectangular region surrounded by the gate electrode connecting wire of the compound semiconductor field effect transistor.

FIG. 8(b) is a schematic plan view of a compound semiconductor field effect transistor of a second embodiment of the present invention.

FIG. 8(c) is a schematic plan view of the compound semiconductor field effect transistor of the second embodiment of the present invention.

FIG. 9(a) is an equivalent circuit diagram of the compound semiconductor field effect transistor illustrated in FIG. 8(a).

FIG. 9(b) is an equivalent circuit diagram of the compound semiconductor field effect transistor illustrated in FIG. 8(b).

FIG. 10(a) is a schematic plan view of a compound semiconductor field effect transistor of a third embodiment of the present invention.

FIG. 10(b) is an equivalent circuit diagram of the compound semiconductor field effect transistor illustrated in FIG. 10(a).

FIG. 10(c) is a schematic plan view of a compound semiconductor field effect transistor of the third embodiment of the present invention.

FIG. 11(a) is a schematic plan view of a compound semiconductor field effect transistor of a fourth embodiment of the present invention.

FIG. 11(b) is a schematic plan view of a compound semiconductor field effect transistor of the fourth embodiment of the present invention.

FIG. 12(a) is a schematic plan view of a modification example of a compound semiconductor field effect transistor of a fifth embodiment of the present invention.

FIG. 12(b) is a schematic plan view of a compound semiconductor field effect transistor of the fifth embodiment of the present invention.

FIG. 12(c) is a schematic plan view of a compound semiconductor field effect transistor of the fifth embodiment of the present invention.

FIG. 12(d) is a schematic plan view of another modification example of the compound semiconductor field effect transistor of the fifth embodiment of the present invention.

FIG. 13(a) is a schematic plan view of a compound semiconductor field effect transistor of a sixth embodiment of the present invention.

FIG. 13(b) is a schematic plan view of a compound semiconductor field effect transistor of the sixth embodiment of the present invention.

FIG. 13(c) is a graph showing the finger length dependency of the gate voltage change ΔV.

FIG. 14 is a diagram illustrating a field effect transistor described in PTL 1.

FIG. 15 is a diagram illustrating a field effect transistor described in PTL 2.

### DESCRIPTION OF EMBODIMENTS

Detailed description will be given below of the present invention with reference to the illustrated embodiments.

### First Embodiment

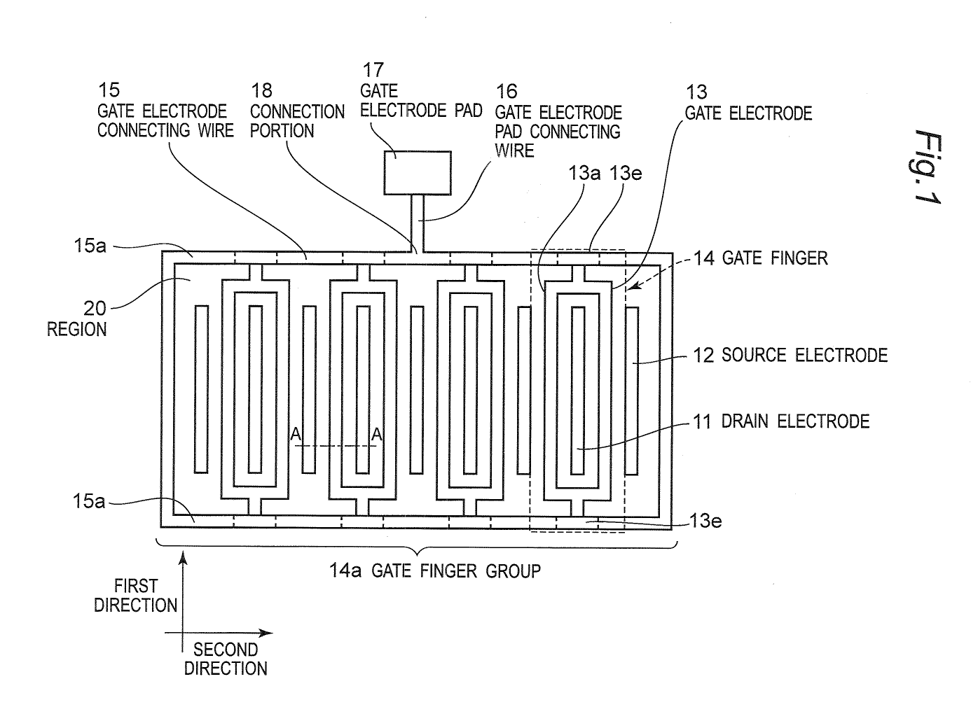

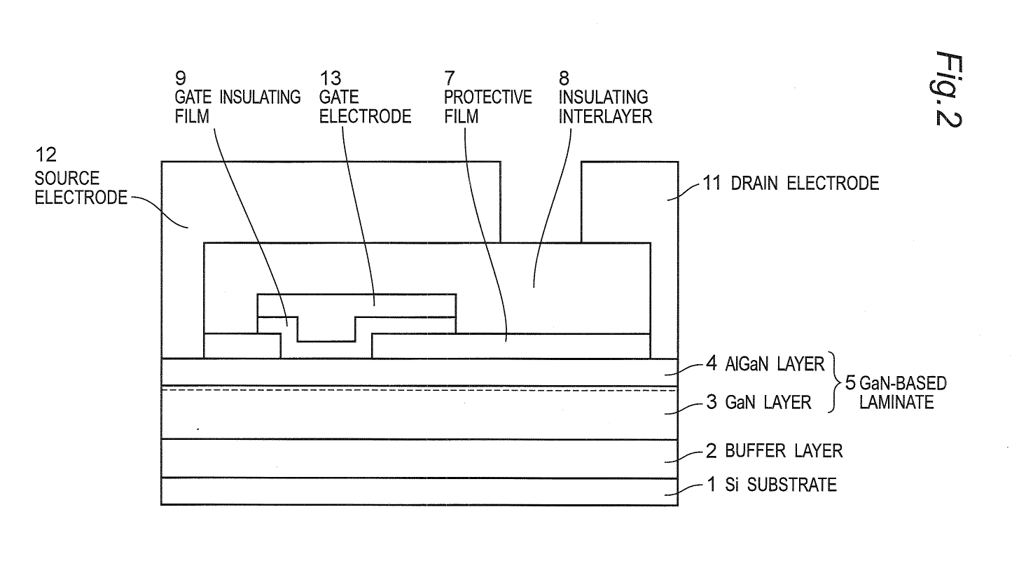

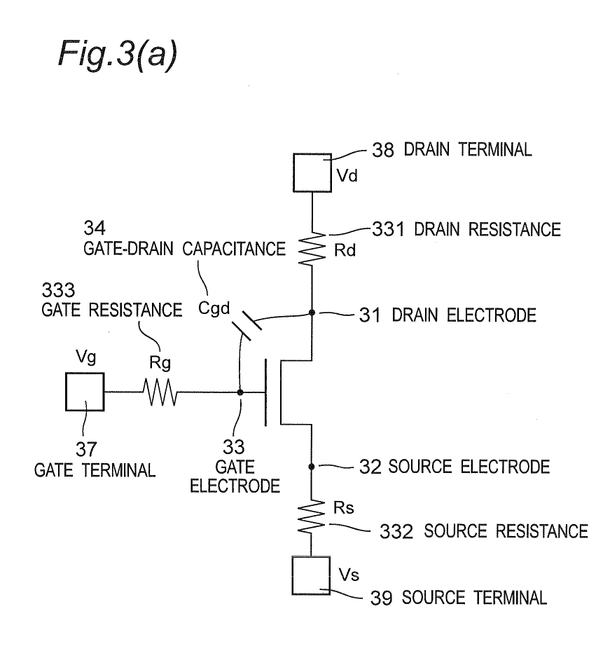

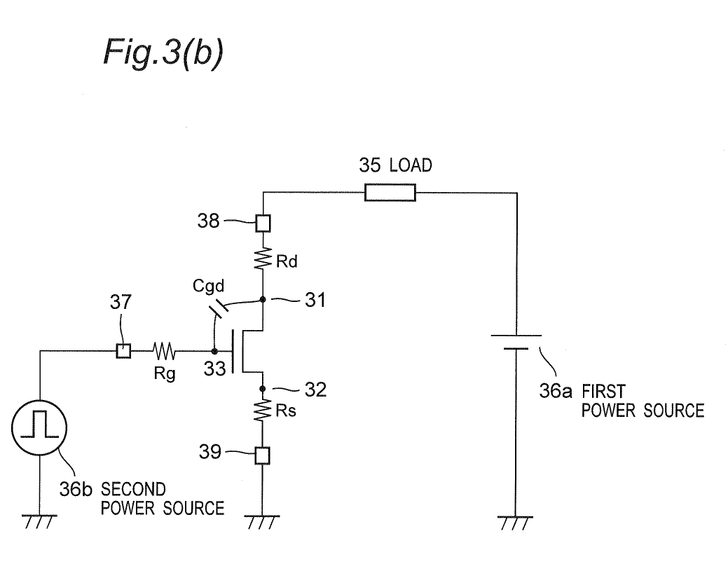

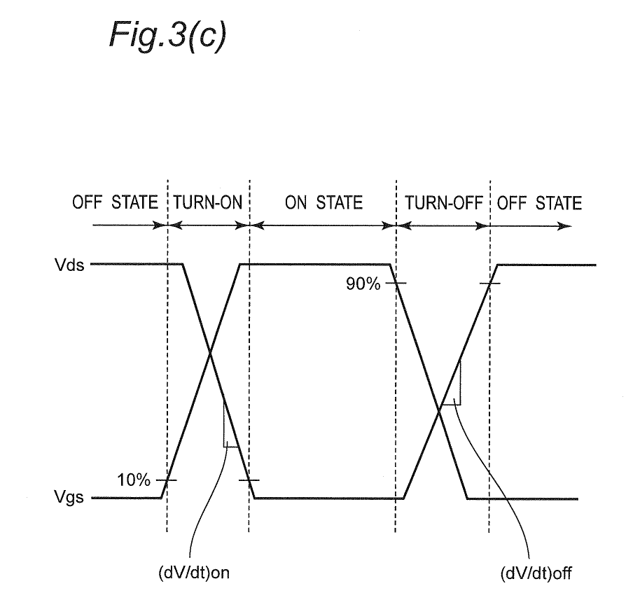

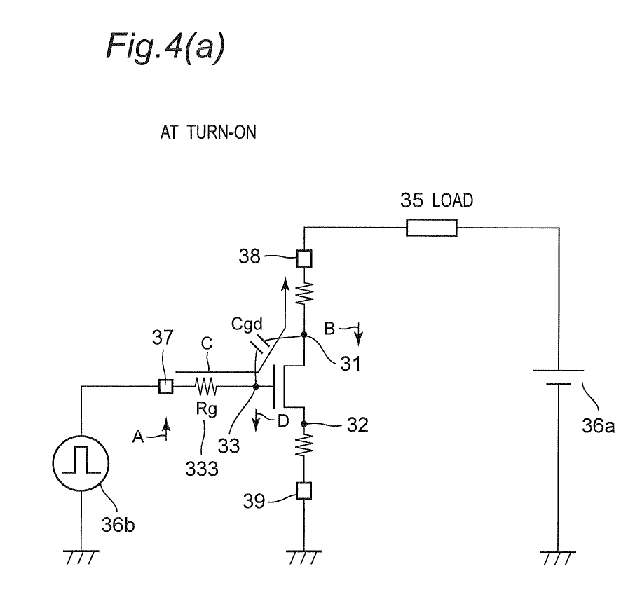

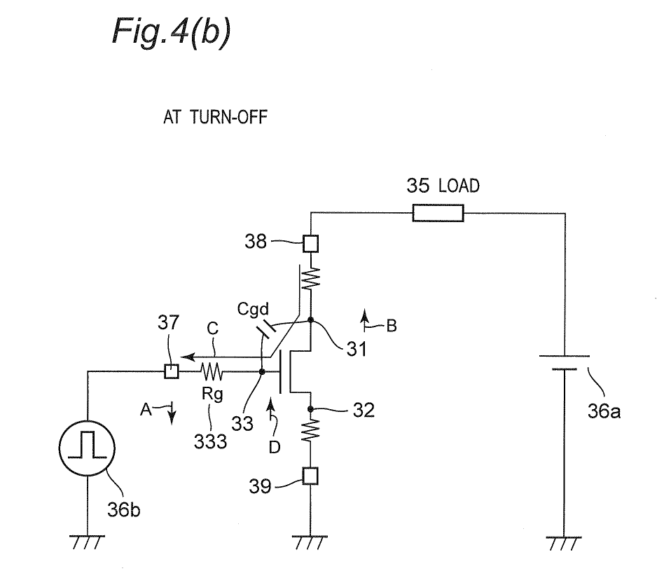

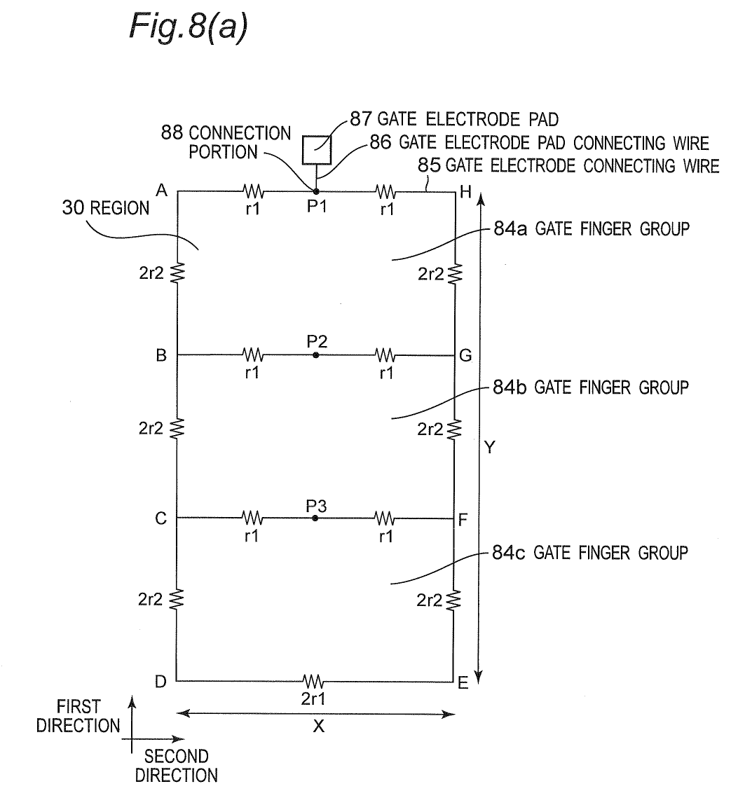

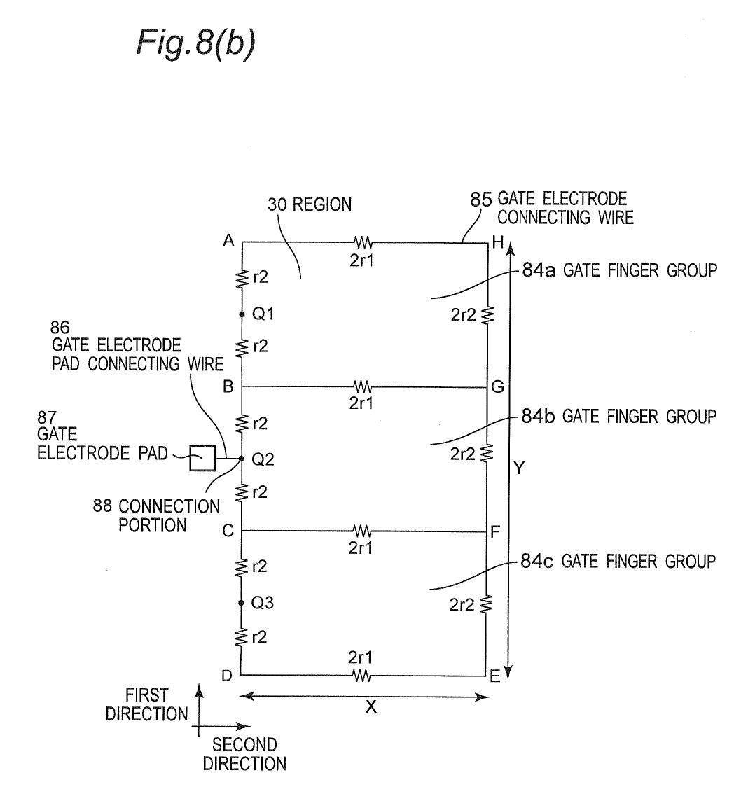

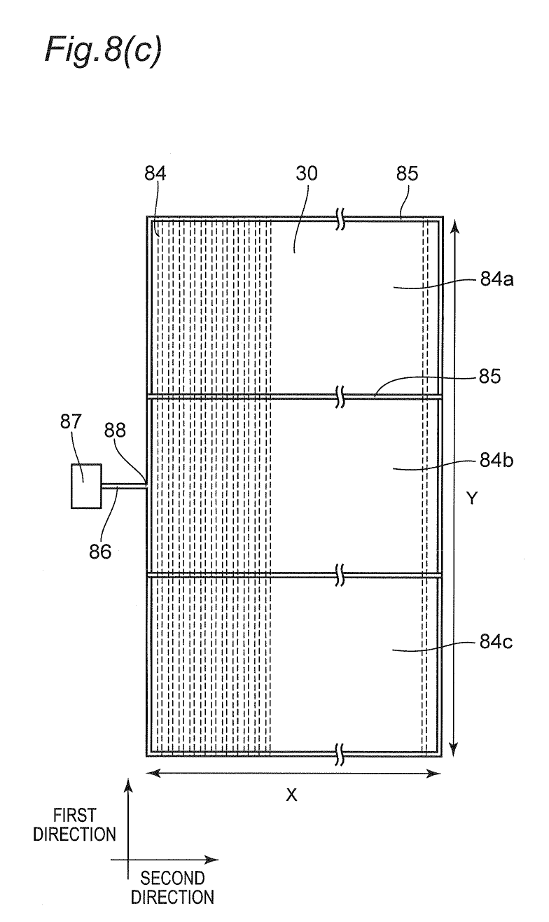

FIG. 1 and FIGS. 8(b) and 8(c) are schematic plan views of a GaN-based heterojunction field effect transistor (HFET) of the first embodiment as an example of the compound semiconductor field effect transistor of the present invention. In addition, FIG. 2 is a sectional view which illustrates a section taken along a line A-A in FIG. 1.

As illustrated in FIG. 2, in the GaN-based HFET of the first embodiment, a buffer layer 2, a GaN layer 3, and an AlGaN layer 4 are formed in order on a Si substrate 1. The GaN layer 3 and the AlGaN layer 4 form a GaN-based laminate 5 having a heterojunction. The buffer layer 2, the GaN layer 3, and the AlGaN layer 4 are examples of semiconductor layers.

Two-dimensional electron gas (2DEG) is generated at the interface between the GaN layer 3 and the AlGaN layer 4 to form a channel.

Note that, the substrate 1 is not limited to a Si substrate and a sapphire substrate or a SiC substrate may be used, the GaN-based laminate 5 may be grown on a sapphire substrate or a SiC substrate, or the GaN-based laminate 5 may be grown on a substrate formed of a nitride semiconductor, such as growing an AlGaN layer on the GaN substrate. In addition, the buffer layer 2 is not necessarily formed on the Si substrate 1.

On the GaN-based laminate 5, a protective film 7 and an insulating interlayer 8 are formed in order as an insulating layer. As the material of the protective film 7, for example, SiN is used here; however, SiO₂, Al₂O₃, or the like may be used. In addition, as the material of the insulating interlayer 8, for example, a SiO₂ film formed by a chemical vapor deposition method (CVD method) is used here; however, an insulating material such as Spin On Glass (SOG), Boron Phosphorous Silicate Glass (BPSG), or the like may be used. In addition, the thickness of the SiN protective film 7 is set to 150 nm here as an example; however, the thickness may be set within a range of 20 nm to 250 nm.

A recess reaching the AlGaN layer 4 is formed in the protective film 7 and the insulating interlayer 8 through the protective film 7 and the insulating interlayer 8, and the drain electrode 11 and the source electrode 12 are formed in the recess. The drain electrode 11 and the source electrode 12 are formed of, for example, a Ti/AlCu/TiN electrode or the like in which a Ti layer, an AlCu layer, and a TiN layer are laminated in order, and the AlCu film thickness is 1,000 nm to 3,000 nm.

An opening is formed in the protective film 7 between the drain electrode 11 and the source electrode 12. A gate insulating film 9 and the gate electrode 13 are formed in the opening and the vicinity thereof. The gate electrode 13 is covered with the insulating interlayer 8. A gate electrode pad (not shown), a drain electrode pad (not shown), and a source electrode pad (not shown) are formed on the insulating interlayer 8. The gate insulating film 9 is formed of a SiN film or the like. The gate electrode 13 is formed of, for example, WN/W/Au.

As illustrated in FIG. 1, the drain electrode 11 and the source electrode 12 extend in a finger shape in a first direction in plan view and a plurality thereof are arranged alternately substantially parallel to each other at intervals determined in advance in a second direction substantially orthogonal to the first direction.

In addition, the gate electrode 13 extends in the first direction between the finger-shaped drain electrode 11 and the finger-shaped source electrode 12 in plan view and has a substantially rectangular loop-shaped portion 13a surrounding the periphery of the drain electrode 11.

Both ends 13e, 13e of the gate electrode 13 in the first direction are electrically connected to opposing portions 15a, 15a, which are long side portions of a substantially rectangular loop-shaped gate electrode connecting wire 15 having a long side and a short side. The outer edge of the substantially rectangular loop-shaped gate electrode connecting wire 15 having a long side and a short side defines the substantially rectangular region 20 inside the outer edge, that is, the region between the outer edges of the opposing portions 15a, 15a is the substantially rectangular region 20. In plan view, the drain electrode 11, the source electrode 12 and the gate electrode 13 are included inside the substantially rectangular loop-shaped gate electrode connecting wire 15 having the long side and the short side, that is, in the substantially rectangular region 20.

In addition, the gate electrode pad 17 is arranged outside the substantially rectangular loop-shaped gate electrode connecting wire 15 and on the side in the first direction, that is, outside the opposing portion 15. The gate electrode pad 17 and the midpoint 18 of the opposing portion 15a which is the long side portion of the substantially rectangular loop-shaped gate electrode connecting wire 15 are electrically connected by the gate electrode pad connecting wire 16. The midpoint 18 is the connection portion 18 included in the gate electrode connecting wire 15. Note that, this midpoint 18 is not a midpoint in the mathematical strict sense, but a midpoint in the engineering sense and means a position distributed evenly with which the distribution of resistance is not an engineering problem. The gate electrode pad connecting wire 16 extends in the first direction from the connection portion 18.

The gate electrode connecting wire 15 and the gate electrode pad connecting wire 16 are, for example, formed of a Ti/AlCu/TiN electrode or the like in which a Ti layer, an AlCu layer, and a TiN layer are laminated in order.

In addition, the drain electrode 11, the gate electrode 13 surrounding the drain electrode 11, and a part of the gate electrode connecting wire 15 form the gate finger 14. The GaN-based HFET has a plurality of gate fingers 14 arranged in the second direction, and the plurality of gate fingers 14 surrounded by one gate electrode connecting wire 15 form one gate finger group 14a.

According to the compound semiconductor field effect transistor with the above configuration, since the connection portion 18 which is electrically connected to the gate electrode pad connecting wire 17 is arranged on the long side of the substantially rectangular region 20, that is, at substantially the midpoint of the opposing portion 15a of the gate electrode connecting wire 15, the signal delay in the gate finger group 14a is reduced, it is possible to reduce the gate voltage change, to sufficiently suppress ringing and oscillation, to realize a stable uniform operation, and moreover, to secure a high short-circuit resistance.

### Second Embodiment

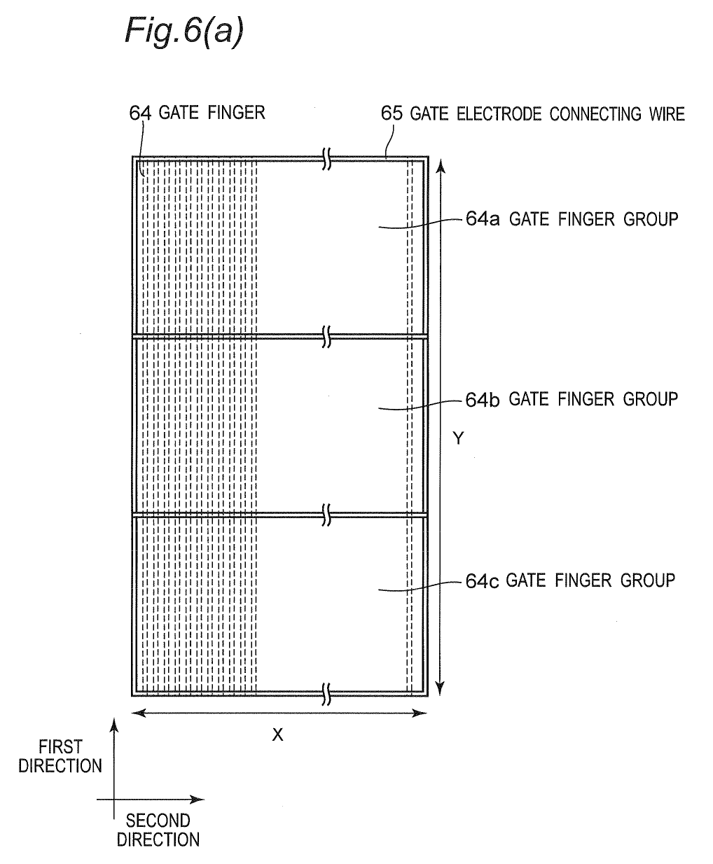

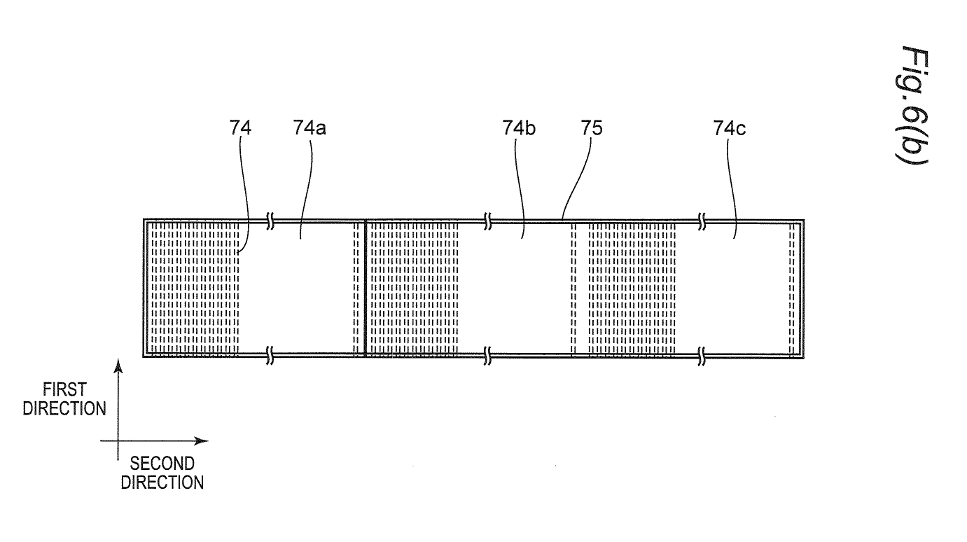

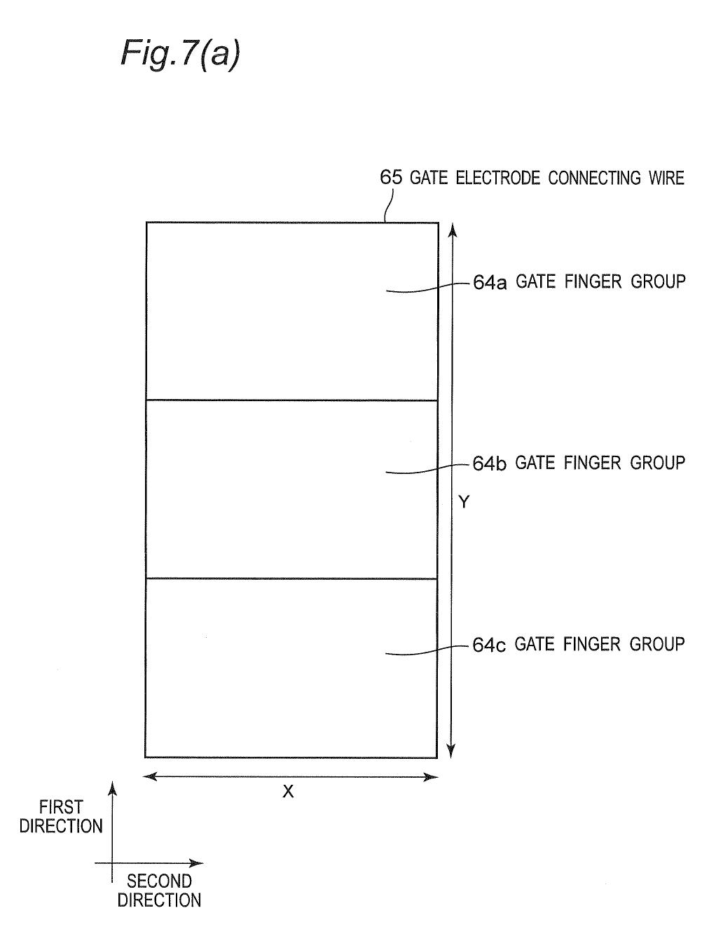

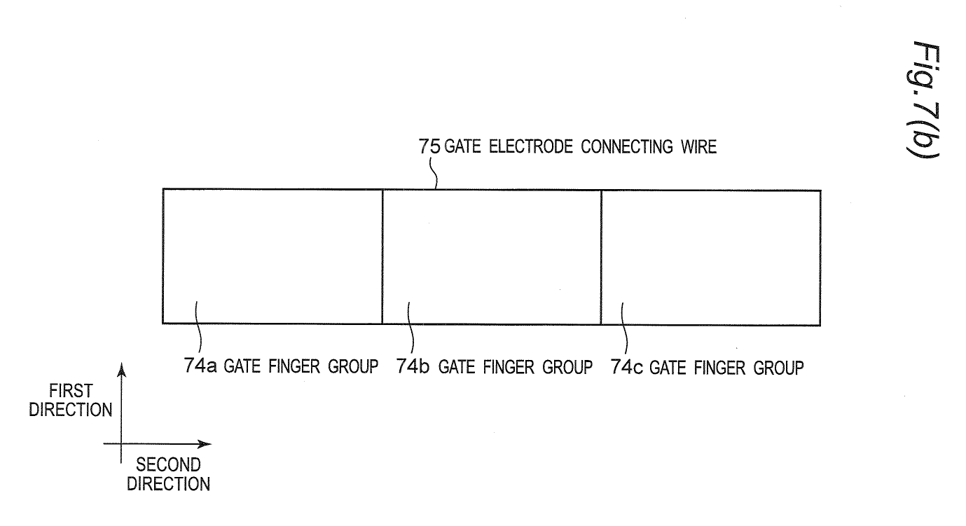

Prior to describing the compound semiconductor field effect transistor of the second embodiment of the present invention, description will be given of arrangement examples of gate finger groups applicable to the present invention with reference to FIG. 6(a), FIG. 7(a), FIG. 6(b), and FIG. 7(b).

In a case where it is desired that a large current flow in the compound semiconductor field effect transistor, a gate finger 64 and the source electrode (not shown) are alternately arranged in the second direction as illustrated in FIG. 6(a) in order to reduce the on resistance, and a plurality of gate finger groups, for example, gate finger groups 64a, 64b, and 64c surrounded by the gate electrode connecting wires 65 are formed. As illustrated in FIG. 6(a), the gate finger groups 64a, 64b, and 64c are arranged in the first direction.

In addition, as illustrated in FIG. 6(b), the plurality of gate finger groups 74a, 74b, and 74c surrounded by the gate electrode connecting wires 75 may be arranged in the second direction.

Below, for the sake of simplicity, FIG. 6(a) is illustrated as FIG. 7(a), FIG. 6(b) is illustrated as FIG. 7(b), and description will be given focusing on the gate finger groups 64a, 64b, 64c, 74a, 74b, and 74c, surrounded by the gate electrode connecting wires 65 and 75.

FIG. 8(a) illustrates a comparative example and the compound semiconductor field effect transistor of this comparative example has gate finger groups 84a, 84b, and 84c, and gate electrode connecting wire 85 surrounding all the gate finger groups 84a, 84b, and 84c. The gate electrode connecting wire 85 has a substantially ladder-shape, and each portion of the substantially ladder-shaped gate electrode connecting wire 85 surrounds the respective gate finger groups 84a, 84b, and 84c. The outline of the outer periphery of the gate electrode connecting wire 85 is a substantially rectangular shape having a short side and a long side, and defines a rectangular region 30 having a long side and a short side encompassing all the gate finger groups 84a, 84b, and 84c in plan view. The gate finger groups 84a, 84b, and 84c are formed of a plurality of gate fingers 84 (refer to FIG. 8(c)).

In addition, a connection portion 88 positioned at a substantially midpoint of the short side of the gate electrode connecting wire 85 is electrically connected to a gate electrode pad 87 by the gate electrode pad connecting wire 86. In the comparative example in FIG. 8(a), the length of the gate electrode connecting wire 85 in the second direction, that is, the length of the short side, is X, the length in the first direction, that is, the length of the long side, is Y, X≦Y, and the connection portion 88 with the gate electrode pad connecting wire 86 is positioned at a substantial midpoint of the short side.

As illustrated in FIG. 8(a), the four corners of the gate finger group 84a are A, B, G, and H, the four corners of the gate finger group 84b are B, C, F, and G, and the four corners of the gate finger group 84c are C, D, E, and F.

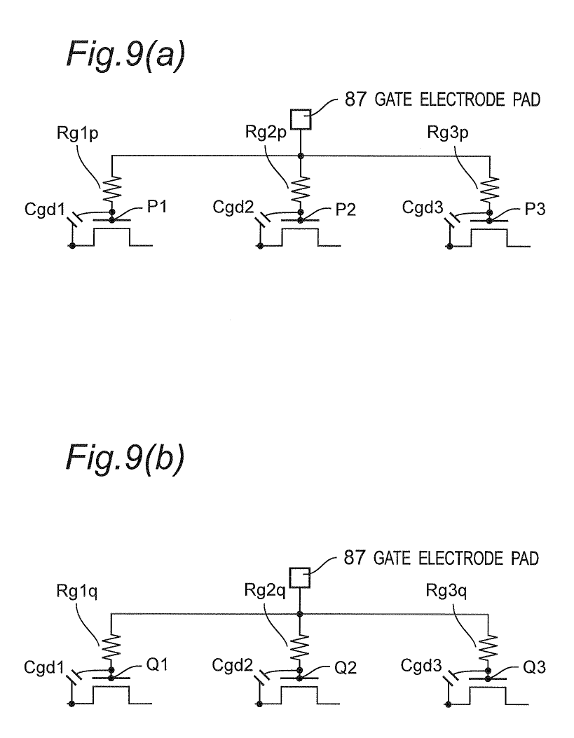

Assuming that the midpoint of AH in FIG. 8(a) is P1, the midpoint of BG is P2, and the midpoint of CF is P3, the equivalent circuit of each gate finger group viewed from the gate electrode pad 87 is as illustrated in FIG. 9(a). The equivalent gate resistance Rg1p (refer to FIG. 9(a)) of the gate finger group 84a in FIG. 8(a) is represented by the wire resistance between the gate electrode pad 87 and P1, the equivalent gate resistance Rg2p (refer to FIG. 9(a)) of the gate finger group 84b is represented by the wire resistance between the gate electrode pad 87 and 02, and the equivalent gate resistance Rg3p (refer to FIG. 9(a)) of the gate finger group 84c is represented by the wire resistance between the gate electrode pad 87 and 03.

Meanwhile, as illustrated in FIGS. 8(b) and 8(c), the compound semiconductor field effect transistor of the second embodiment has the gate finger groups 84a, 84b, and 84c and a gate electrode connecting wire 85 which surrounds all the gate finger groups 84a, 84b, and 84c. The gate electrode connecting wire 85 has a substantially ladder-shape, and each portion of the substantially ladder-shaped gate electrode connecting wire 85 surrounds the respective gate finger groups 84a, 84b, and 84c. The outline of the outer periphery of the gate electrode connecting wire 85 is a substantially rectangular shape having a short side and a long side and defines the substantially rectangular region 30 including all the gate finger groups 84a, 84b, and 84c. Both ends of the gate electrode of the gate fingers 84 of the gate finger group 84a, 84b, and 84c are electrically connected to the gate electrode connecting wire 85.

In addition, the connection portion 88 positioned at a substantially midpoint of the long side of the gate electrode connecting wire 85 is electrically connected to the gate electrode pad 87 by the gate electrode pad connecting wire 86. In FIGS. 8(b) and 8(c) of the second embodiment, when the length of the gate electrode connecting wire 85 in the second direction, that is, the length of the short side, is X and the length in the first direction, that is, the length of the long side, is Y, X≦Y, and the connection portion 88 with the gate electrode pad connecting wire 86 is positioned at substantially the midpoint of the long side.

As illustrated in FIG. 8(b), the four corners of the gate finger group 84a are A, B, G, and H, the four corners of the gate finger group 84b are B, C, F, and G, and the four corners of the gate finger group 84c are C, 0, E, and F.

Assuming that the midpoint of AB in FIG. 8(b) is Q1, the midpoint of BG is Q2, and the midpoint of CF is Q3, the equivalent circuit of each gate finger group viewed from the gate electrode pad 87 is as illustrated in FIG. 9(b). The equivalent gate resistance Rg1q (refer to FIG. 9(b)) of the gate finger group 84a in FIG. 8(b) is represented by the wire resistance between the gate electrode pad 87 and Q1, the equivalent gate resistance Rg2q (refer to FIG. 9(b)) of the gate finger group 84b is represented by the wire resistance between the gate electrode pad 87 and Q2, and the equivalent gate resistance Rg3q (refer to FIG. 9(b)) of the gate finger group 84c is represented by the wire resistance between the gate electrode pad 87 and Q3.

Note that, in FIG. 8(a) and FIG. 8(b), r1 and r2 are resistances represented by distributed constants. In addition, in FIGS. 9(a) and 9(b), Cgd1, Cgd2, and Cgd3 represent gate-drain capacitances.

In FIG. 8(a) and FIG. 8(b), assuming that X=2,500 μm and Y=5,000 μm, the wire widths are all 30 μm, and the sheet resistance of the wire is 18 mΩ/□, the resistance value of AH=BG=CF-DE is 2,500/30×18 mΩ≅1.5Ω, and the resistance value of AB=HG=BC=GF=CD=FE is 5,000/30×18 mΩ/3≅1Ω. That is, r1=0.75Ω, and r2=0.5Ω.

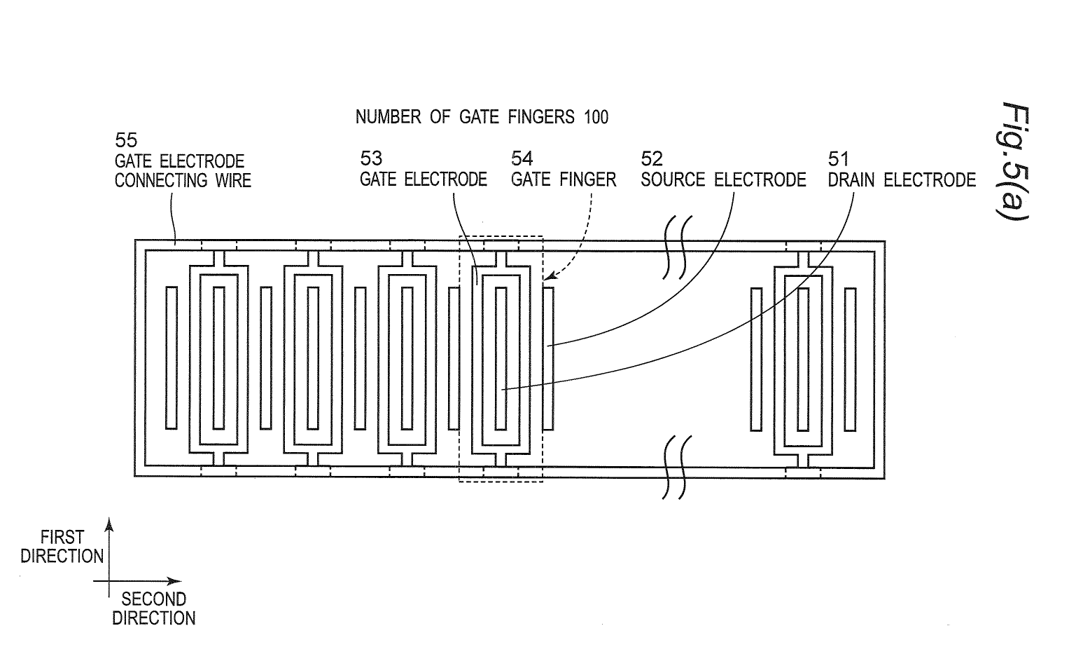

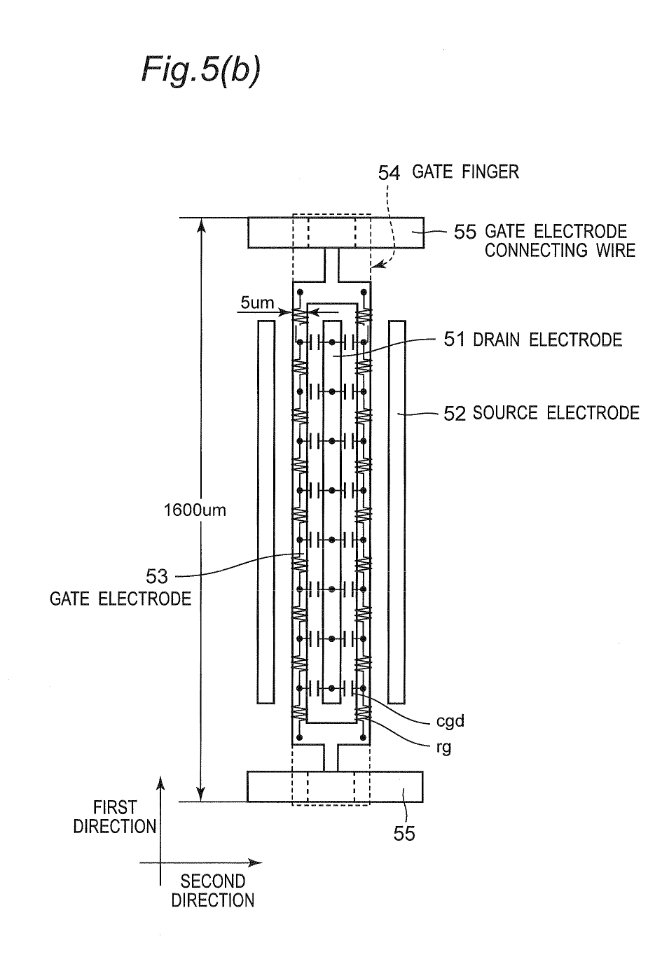

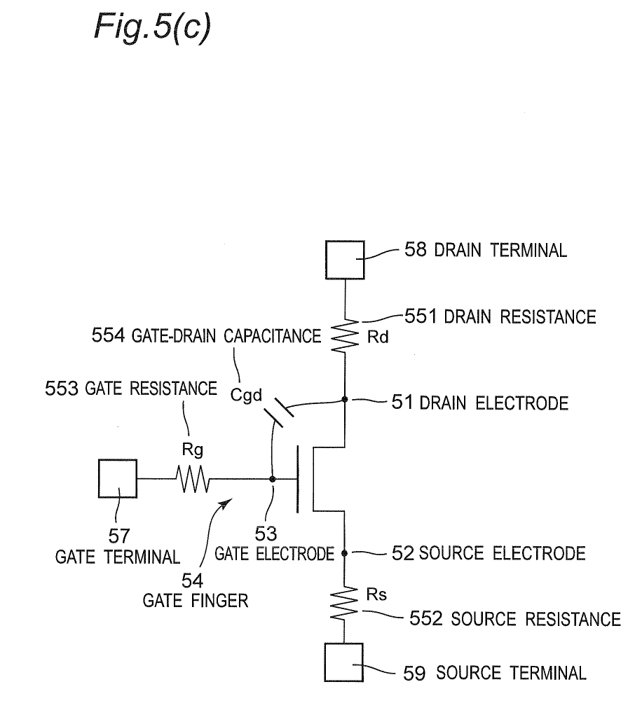

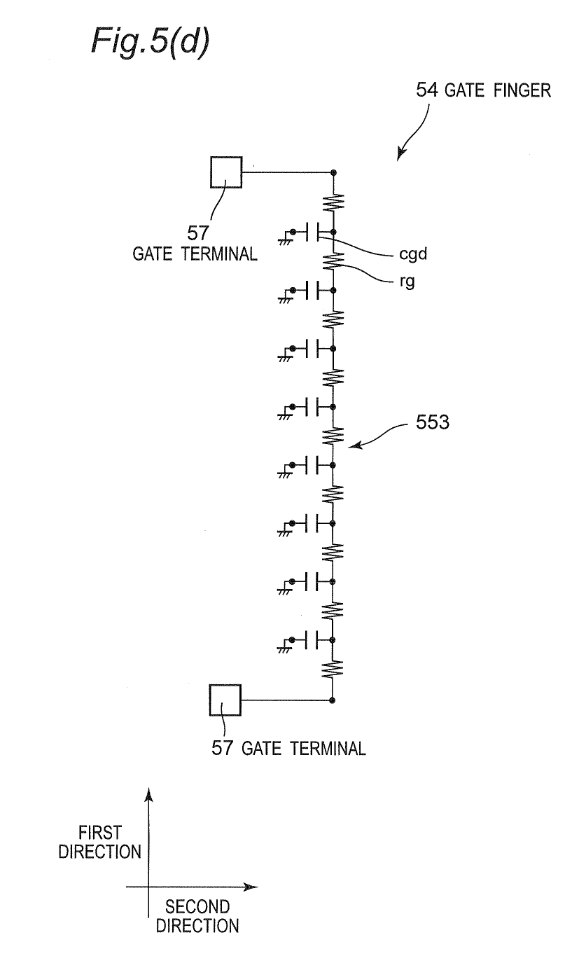

The gate voltage changes in the respective gate finger groups illustrated in FIGS. 9(a) and 9(b) are indicated by the equations (1) and (2) as described above, and represented by ΔV=Rg×Cgd×(dV/dt)off, (dV/dt)off is represented by 100 V/ns as in FIG. 5, and Cgd1=Cgd2=Cgd3 is represented by 50 pF/317 pF.

In FIG. 9(a), the largest equivalent gate wire resistance is Rg3p from the gate electrode pad 87 to 93, Rg3p≅1.75Ω, whereas in FIG. 9(b), the largest equivalent gate wire resistance is from the gate electrode pad 87 to Q1 or Q3, and Rg1q=Rg3q=2r2≅1Ω.

Accordingly, as in the comparative example illustrated in FIGS. 8(a) and 9(a), in a case where the gate electrode pad 87 is arranged on the short side of the rectangular region 30, that is, the short side of the gate electrode connecting wire 85 forming the rectangular region 30, the gate voltage change ΔVa in the gate finger group is ΔVa=Rg3p×Cgd3×(dV/dt)off≅1.75×17×100=3 V.

On the other hand, as in the second embodiment illustrated in FIG. 8(b) and FIG. 9(b), in a case where the gate electrode pad 87 is arranged on the long side of the rectangular region 30, that is, the long side of the gate electrode connecting wire 85 forming the rectangular region 30, the gate voltage change ΔVb in the gate finger group is ΔVb=Rg1g×Cgd1×(dV/dt)off≅1.0×17×100=1.7 V.

That is, since the compound semiconductor field effect transistor according to the second embodiment is provided with the connection portion 88 between the gate electrode pad 87 and the gate electrode connecting wire 85 at the midpoint on the long side of the gate electrode connecting wire 85, in comparison with the case where the connection portion 88 is provided at the midpoint on the short side of the gate electrode connecting wire 85 as in the comparative example, it is possible to lower the gate voltage change in the gate finger group, to sufficiently suppress ringing and oscillation, to realize a stable operation, and to secure a high short-circuit resistance.

### Third Embodiment

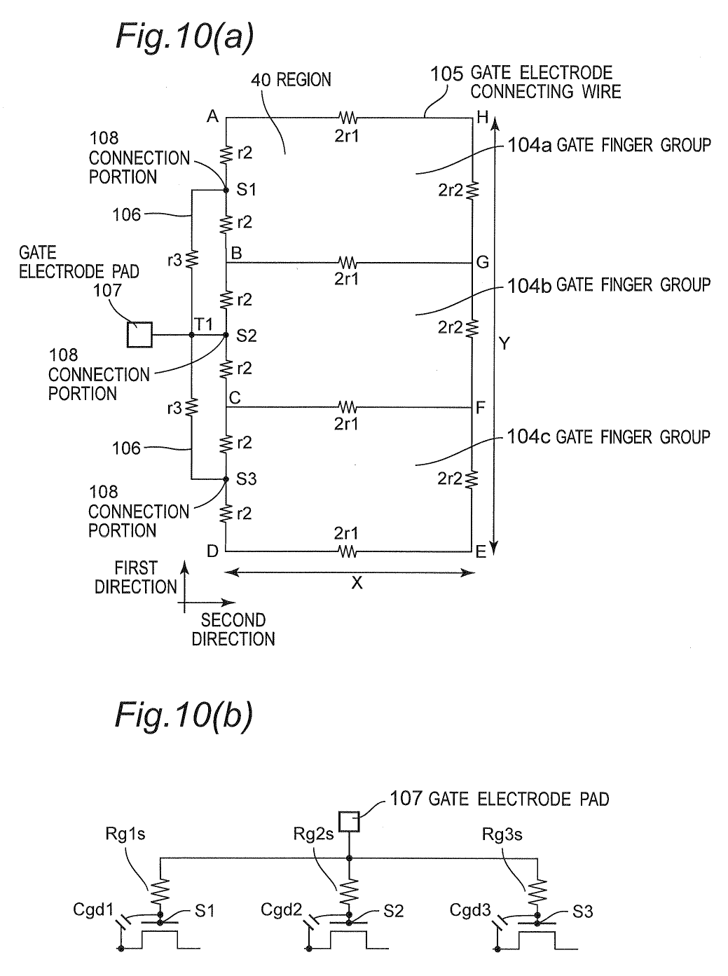

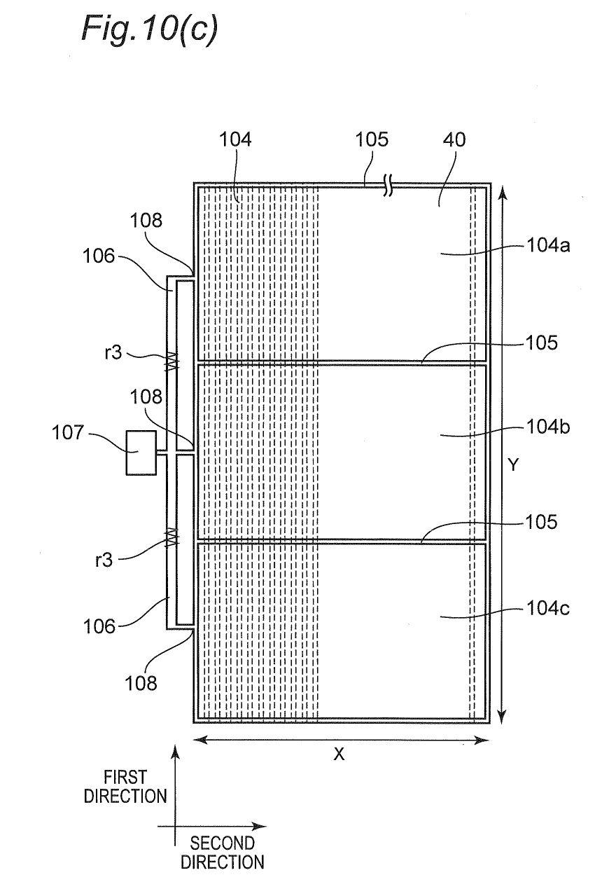

FIG. 10(a) is a schematic plan view of a compound semiconductor field effect transistor of the third embodiment of the present invention, FIG. 10(b) is an equivalent circuit diagram of the compound semiconductor field effect transistor in FIG. 10(a), and FIG. 10(c) is a schematic plan view of a compound semiconductor field effect transistor in FIG. 10(a).

As illustrated in FIGS. 10(a) and 10(c), in the same manner as the second embodiment in FIG. 8(b), the compound semiconductor field effect transistor of the third embodiment has a plurality of gate finger groups 104a, 104b, and 104c and has a ladder-shaped gate electrode wire 105. Both ends of the gate electrodes of the gate fingers 104 (refer to FIG. 10(c)) of the gate finger groups 104a, 104b, and 104c are electrically connected to the opposing portions of the gate electrode connecting wire 105. The outermost periphery of the gate electrode connecting wire 105 is a substantially rectangular shape having a long side and a short side, and defines a substantially rectangular region 40 encompassing all the gate finger groups 104a, 104b, and 104c.

In a case where the length of the gate electrode wire 105 in the second direction is X and the length in the first direction is Y (X≦Y), connection portions 108, 108, 108 between a gate electrode pad 107 and gate electrode wire 105 are provided on the long side of the gate electrode wire 105 where the outermost periphery is substantially rectangular, and the connection portions 108, 108, 108 are positioned at the central portions of the long side, for example, the midpoints S1, S2, and S3 in each of the gate finger groups 104a, 104b, and 104c.

Note that, in FIG. 10(a), r1, r2, and r3 are resistances represented by distributed constants.

As illustrated in FIG. 10(a), the connection portions 108, 108, 108 positioned at the midpoints S1, S2, and S3 of the portion of the long side in the gate electrode connecting wires 105 belonging to adjacent gate finger groups 104a, 104b, and 104c are interconnected by two first gate electrode pad connecting wires 106, 106, and the connection point T1 of the two first gate electrode pad connecting wires 106, 106 is connected to the gate electrode pad 107.

The first gate electrode pad connecting wire 106 is formed of, for example, an aluminum wire and extends substantially parallel to the first direction, that is, in the extending direction of the gate finger 104.

FIG. 10(b) illustrates an equivalent circuit of the main portion of the compound semiconductor field effect transistor of the third embodiment, the equivalent gate resistance Rg1s of the gate finger group 104a is represented by the wire resistance Rg1s between the gate electrode pad 107 and the midpoint S1, the equivalent gate resistance Rg2s of the gate finger group 104b is represented by the wire resistance Rg2s between the gate electrode pad 107 and the midpoint S2, and the equivalent gate resistance Rg3s of the gate finger group 104c is represented by the wire resistance Rg3s between the gate electrode pad 107 and the midpoint S3.

The gate voltage change ΔV in the respective gate finger groups 104a, 104b, and 104c illustrated in FIGS. 10(a), 10(b) and 10(c) is expressed as in equations (1) and (2) as above and represented by ΔV=Rg×Cgd×(dV/dt)off.

On the other hand, in the same manner as the first embodiment in FIG. 5(c), (dV/dt)off is expressed as 100 V/ns and Cgd1=Cgd2=Cgd3 as 50 pF/3≅17 pF.

The largest equivalent gate wire resistance in FIG. 10(b) is Rg1s from the gate electrode pad 107 up to the midpoint S1 or Rg3s up to the midpoint S3. For example, assuming Rg1s is the parallel connection of the resistance 2r2=1Ω between the midpoints S1 and S2 and the resistance r3 between the connection point T1 and the midpoint S1 and the wire between the connection point T1 and the midpoint S1 is also 30 μm equivalent to the gate electrode connecting wire 105, r3 also becomes 1Ω, Rg1s=1/(1+1)=0.5Ω, and the gate voltage change ΔV is

ΔV=Rg1s×Cgd1(dV/dt)off≅0.5×17×100=0.85 V.

Therefore, according to the compound semiconductor field effect transistor of the third embodiment, compared to the second embodiment illustrated in FIG. 8(b), it is possible to further educe the gate resistance, it is possible to sufficiently suppress ringing and oscillation, to realize a stable operation, and to secure a high short-circuit resistance.

### Fourth Embodiment

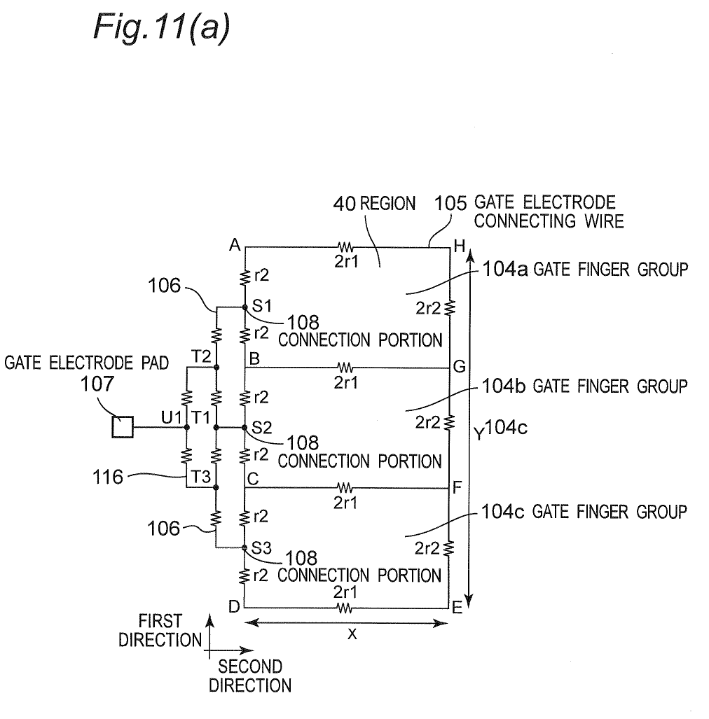

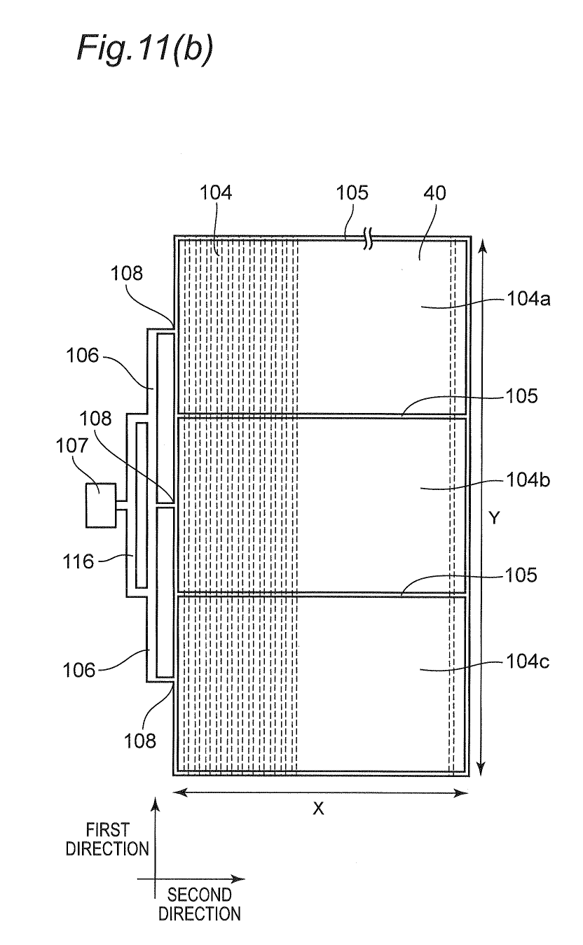

FIGS. 11(a) and 11(b) are schematic plan views of a compound semiconductor field effect transistor according to the fourth embodiment of the present invention.

In the compound semiconductor field effect transistor of the fourth embodiment illustrated in FIGS. 11(a) and 11(b), the same constituent elements as the constituent elements of the compound semiconductor field effect transistor of the third embodiment illustrated in FIGS. 10(a) and 10(c) are denoted by the same reference numerals as the constituent elements illustrated in FIGS. 10(a) and 10(c), and a detailed description thereof will be omitted.

As illustrated in FIGS. 11(a) and 11(b), the compound semiconductor field effect transistor of the fourth embodiment has a plurality of gate finger groups 104a, 104b, and 104c, and, in a case where the length in the second direction of the gate electrode connecting wire 105 having a substantially rectangular outer periphery having long sides and short sides is X and the length in the first direction is Y (X≦Y), the connection portions 108, 108, 108 connecting the gate electrode pad 107 and the gate electrode connecting wire 105 are provided on the long side of the gate electrode connecting wire 105 with a substantially rectangular outer periphery, and the connection portions 108, 108, 108 are positioned on the central portion of the long side in the respective gate finger groups 104a, 104b, and 104c, for example, at the midpoints S1, 52, and S3.

The connection portions 108, 108, 108 positioned at the midpoints S1, S2, and S3 of the portion of the long side in the gate electrode connecting wires 105 belonging to the adjacent gate finger groups 104a, 104b, and 104c are interconnected by two first gate electrode pad connecting wires 106, 106, and respective midpoints T2 and T3 of the two first gate electrode pad connecting wires 106, 106 are interconnected by the second gate electrode pad connecting wire 116. Further, a midpoint U1 of the second gate electrode pad connecting wire 116 is connected to the gate electrode pad 107. Note that, T1 represents the connection point of the two first gate electrode pad connecting wires 106, 106.

The first and second gate electrode pad connecting wires 106 and 116 are formed of, for example, aluminum wire and substantially extend parallel to the first direction, that is, in the extending direction of the gate fingers 104.

In the third embodiment illustrated in FIGS. 10(a), 10(b), and 10(c), the gate resistances Rg1s and Rg3s of the respective finger groups 104a and 104c are large and approximately 0.5Ω, and, in comparison with Rg2s (≅0Ω), the gate resistance difference between the respective finger groups 104a, 104b, and 104c is approximately 0.5Ω.

On the other hand, according to the fourth embodiment as illustrated in FIGS. 11(a) and 11(b), each finger group 104a, 104b, and 104c is connected by the first and second gate electrode pad connecting wires 106 and 116 in a tournament shape (that is, a ladder shape) to the gate electrode pad 107 and the gate resistance differences between the respective gate finger groups 104a, 104b, and 104c is substantially zero and, in comparison with the third embodiment, it was found that the gate resistance is greatly reduced.

Accordingly, according to the fourth embodiment, since it is possible to minimize the gate resistance difference between the gate finger groups 104a, 104b, and 104c, it is possible to sufficiently suppress ringing and oscillation, to realize a stable operation, and, in addition, to secure a high short-circuit resistance.

In the fourth embodiment, there are three gate finger groups 104a, 104b, and 104c, and the gate electrode pad connecting wire is of two types, the first and second gate electrode pad connecting wires 106, 116; however, naturally, it is possible to generalize the number of gate finger groups in the long side direction as N (N is a natural number, N≧3) as described below.

That is, the number of the gate finger groups is N (N is a natural number and N≧3), the connection portions positioned at the midpoint of the portion of the long side in the gate electrode connecting wires belonging to adjacent gate finger group are interconnected with (N−1) first gate electrode pad connecting wires, here, m=a natural number of 1 to (N−2), midpoints of the m-th gate electrode pad connecting wire of (N−m) adjacent wires are interconnected with the (m+1)-th gate electrode pad connecting wire of (N−(m+1)) wires, and a midpoint of the (N−1)-th gate electrode pad connecting wire of the last wire may naturally be connected to the gate electrode pad.

In the description in FIG. 11(b), the first and second gate electrode pad connecting wires 106 and 116 forming the ladder wiring are described as a single layer aluminum wire; however, it goes without saying that setting a wire connection with multiple layers in a laminated structure has the same effect.

### Fifth Embodiment

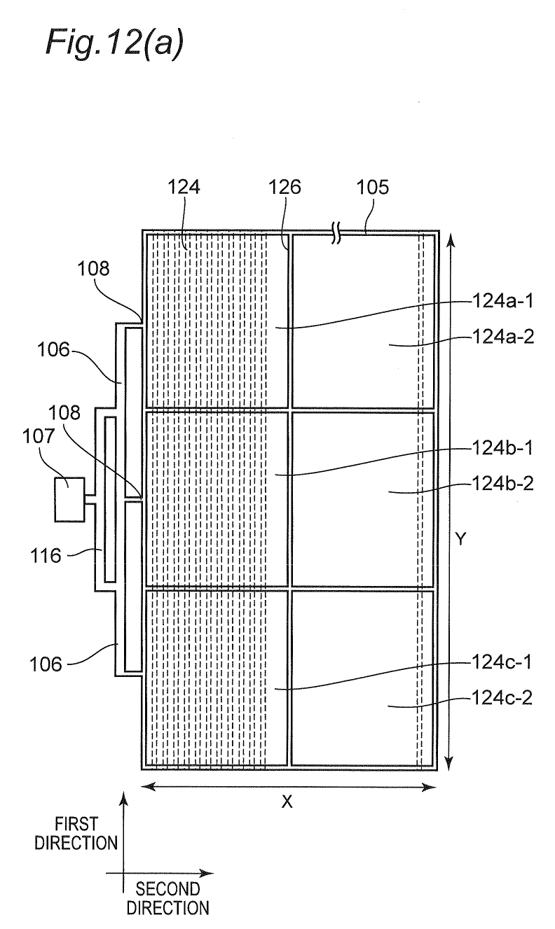

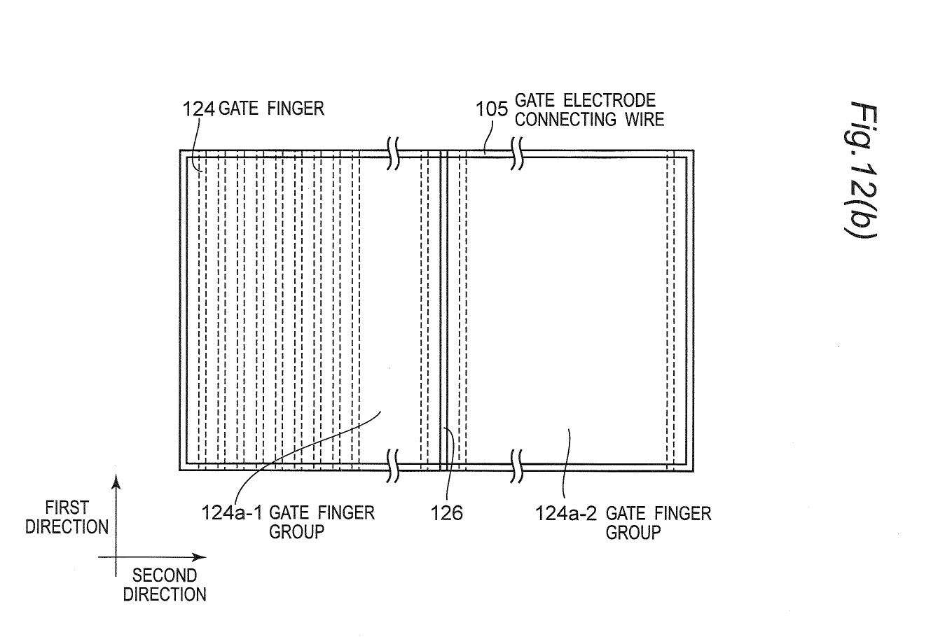

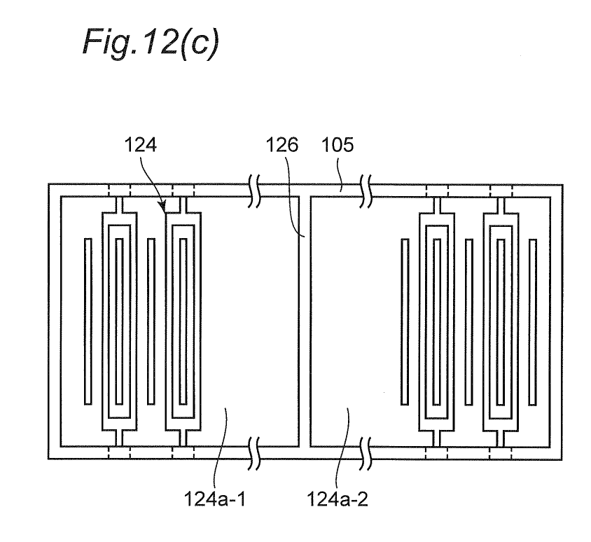

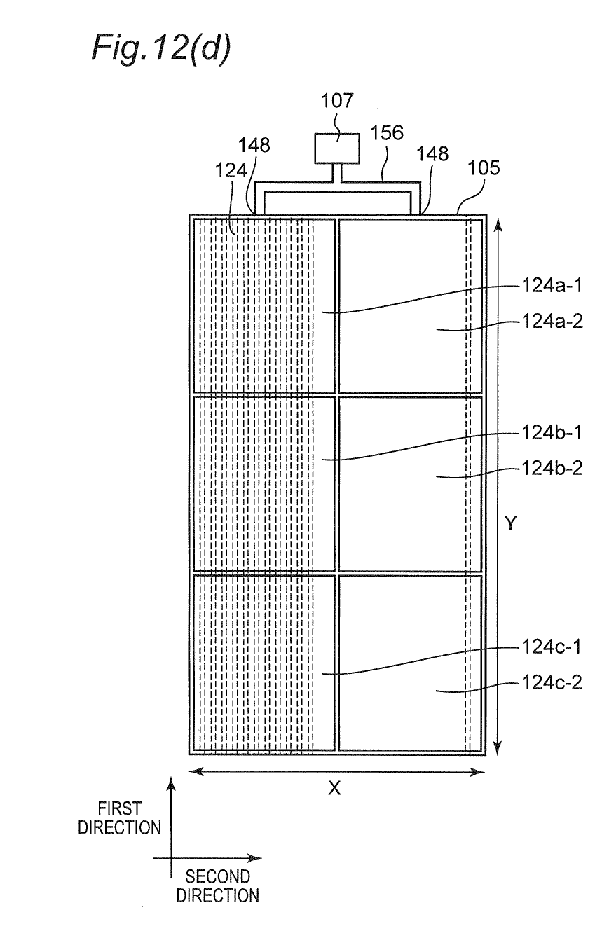

FIG. 12(a) is a schematic plan view of a compound semiconductor field effect transistor according to the fifth embodiment of the present invention, and FIGS. 12(b) and 12(c) are enlarged views of the main portions in FIG. 12(a).

In the compound semiconductor field effect transistor of the fifth embodiment illustrated in FIGS. 12(a), 12(b) and 12(c), the same constituent elements as the constituent elements of the compound semiconductor field effect transistor of the fourth embodiment illustrated in FIGS. 11(a) and 11(b) are denoted by the same reference numerals as the constituent elements illustrated in FIGS. 11(a) and 11(b), and a detailed description thereof will be omitted.

As illustrated in FIGS. 12(a) and 12(b), in the compound semiconductor field effect transistor of the fifth embodiment, a substantially rectangular ladder-shaped gate electrode connecting wire 105 having a long side and a short side at the outer periphery encompasses all the gate finger groups 124a-1, 124b-1, 124c-1, 124a-2, 124b-2, and 124c-2, and is further divided into the left-side gate finger groups 124a-1, 124b-1, and 124c-1 and the right-side gate finger groups 124a-2, 124b-2, and 124c-2 by a linear wire 126 parallel to the first direction. The wire 126 is electrically connected to each step portion of the ladder-shaped gate electrode connecting wire 126.

The gate finger groups 124a-1, 124b-1, and 124c-1 and the gate finger groups 124a-2, 124b-2, and 124c-2 are arranged in the second direction.

According to the fifth embodiment, since it is possible to make the gate finger groups 124a-1, 124b-1, 124c-1, 124a-2, 124b-2, and 124c-2 into small blocks, it is possible to suppress gate voltage changes in the gate finger groups 124a-1, 124b-1, 124c-1, 124a-2, 124b-2, and 124c-2.

Accordingly, in the compound semiconductor field effect transistor of the fifth embodiment, it is possible to sufficiently suppress ringing and oscillation, to realize a stable operation, and, in addition, to secure a high short-circuit resistance.

In FIG. 12(a), the first and second gate electrode pad connecting wires 106 and 116 forming the ladder wiring are illustrated as a single layer wire; however, it goes without saying that setting a wire connection with multiple layers in a laminated structure has the same effect.

FIG. 12(d) illustrates another modification example of the compound semiconductor field effect transistor of the fifth embodiment. In FIG. 12(d), the same constituent elements as the constituent elements of the modification example illustrated in FIG. 12(a) are denoted by the same reference numerals as the reference numerals illustrated in FIG. 12(a), and a detailed description thereof will be omitted.

In the modification example illustrated in FIG. 12(d), connection portions 148, 148 in the gate electrode connecting wire 105 connecting the gate electrode pad 107 and the gate electrode connecting wire 105 defining a plurality of substantially rectangular regions having long sides and the short sides are positioned on the short side of the substantially rectangular region and the connection portions 148, 148 are positioned at the midpoints of the portions of the short sides in the gate electrode connecting wires 105 belonging to the gate finger groups 124a-1 and 124a-2, the connection portions 148, 148 are connected to each other by the gate electrode pad connecting wire 156, and the midpoint of the gate electrode pad connecting wire 156 is connected to the gate electrode pad 107 to form ladder wiring. The gate electrode pad connecting wire 156 is parallel to the second direction.

Even when the connection portions 148, 148 described above are arranged on the short side of the rectangular region, it is possible to reduce the signal delay using the ladder wiring, to reduce the gate voltage change, to sufficiently suppress ringing and oscillation, to realize a stable operation, and, in addition, to secure a high short-circuit resistance and to improve the non-uniform operations.

Note that, in the modification example described above, there are two gate finger groups 124a-1 and 124a-2 in the second direction; however, three or more gate finger groups may be arranged side by side in the second direction, and multiple-stage ladder wiring such as the multiple-stage gate electrode pad connecting wires 106 and 116 illustrated in FIG. 12(a) may be arranged on the short side of the rectangular region.

Although not illustrated, in all the embodiments, even when ladder wiring is used to connect the gate electrode connecting wire and the gate electrode pad and the ladder wiring is arranged on the short side of the rectangular region, there is an effect of improving the non-uniform operation through the ladder wiring.

### Sixth Embodiment

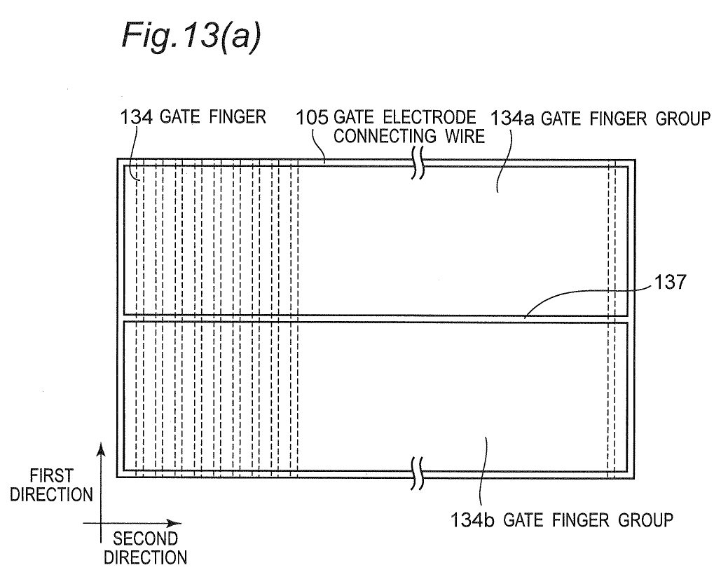

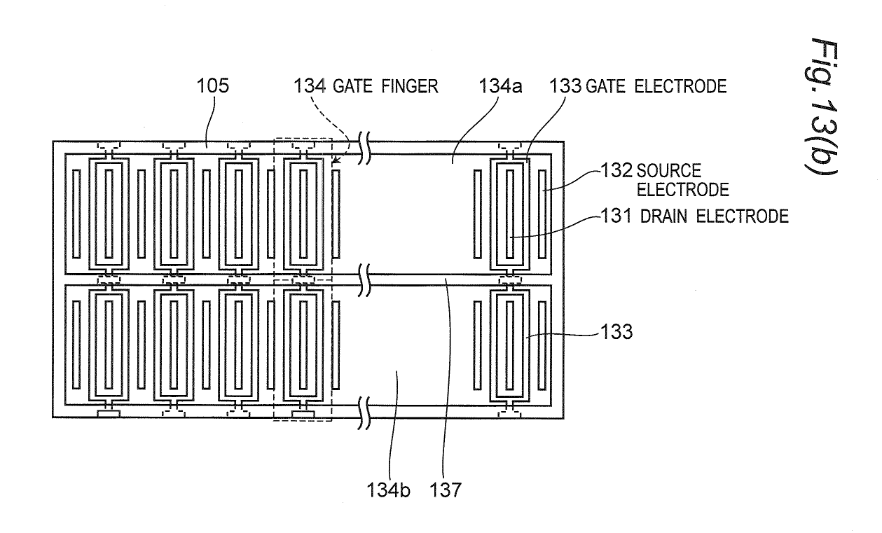

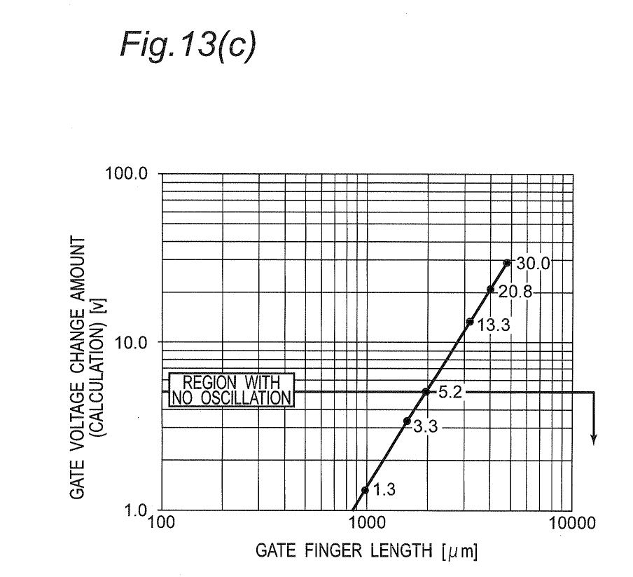

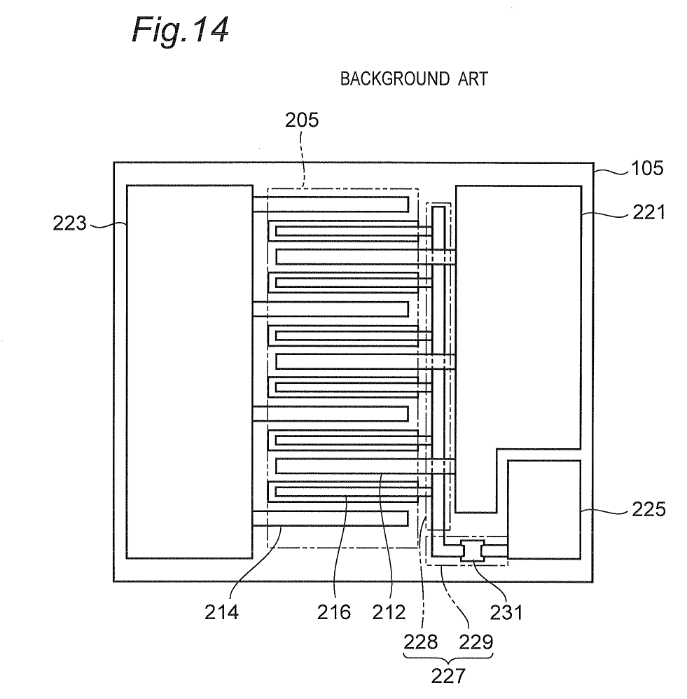

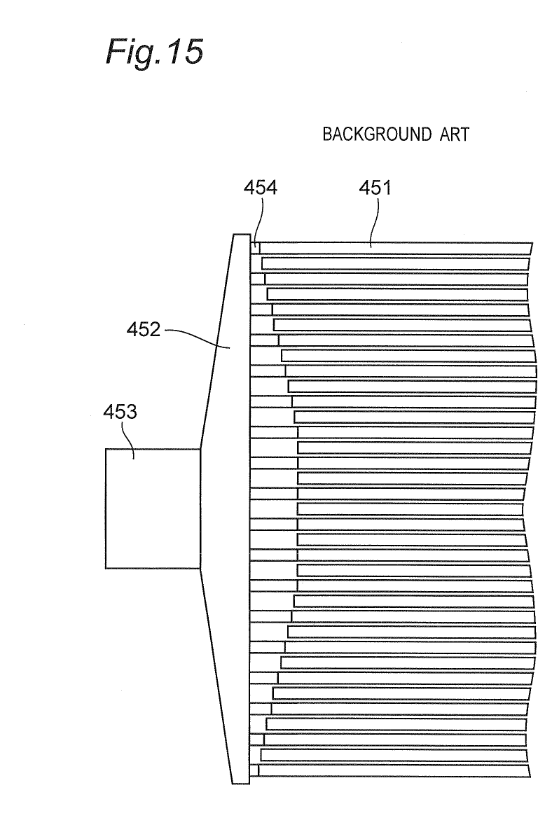

FIGS. 13(a) and 13(b) are schematic plan views of a compound semiconductor field effect transistor according to the sixth embodiment of the present invention.

In the compound semiconductor field effect transistor of the sixth embodiment illustrated in FIGS. 13(a) and 13(b), the same constituent elements as the constituent elements of the compound semiconductor field effect transistor of the fifth embodiment illustrated in FIG. 12(c) are denoted with the same reference numerals as the reference numerals illustrated in FIG. 12(c), and a detailed description thereof will be omitted.

As illustrated in FIGS. 13(a) and 13(b), the compound semiconductor field effect transistor of the sixth embodiment is provided with an additional gate electrode connecting wire 137 which has a linear shape parallel to the second direction and to which a gate electrode 133 is connected so that the compound semiconductor field effect transistor is divided into an upper gate finger group 134a and a lower gate finger group 134b.

In FIG. 13(b), 131 is a drain electrode, 132 is a source electrode, and 134 is a gate finger.

Meanwhile, in order to add the gate electrode connecting wire 137 parallel to the second direction as in the sixth embodiment, it is necessary to reduce the gate finger length.

In FIG. 13(c), the horizontal axis represents the gate finger length and the vertical axis represents the gate voltage change ΔV calculated according to the above-mentioned equations (1) and (2), and the results of actually carrying out a switching operation and testing the oscillation situation are included.

The gate finger length was adjusted to prepare seven levels of 800 μm/1,000 μm/1,600 μm/2,000 μm/3,200 μm/4,000 μm/4,800 μm and the total finger length was fixed (finger length×number of fingers was approximately 160,000 μm). Since the capacitance Cgd as a whole is approximately 50 pF, the capacitance Cgd per finger is calculated from the number of fingers, and dV/dt is calculated as 100 V/nm.

As understood from FIG. 13(c), the operation of the compound semiconductor field effect transistor is stabilized when the gate finger length is 2,000 μm or less; however, oscillation occurs when the gate length exceeds 2,000 μm, and from the calculation result of the gate voltage change, when the gate voltage change is at least approximately 5 V or less, it is considered that it is possible to carry out a stable operation.

Accordingly, it is desirable to set the gate finger length to 2,000 μm or less and, according to the compound semiconductor field effect transistor of the sixth embodiment, since it is possible to make the gate finger groups into small blocks and to suppress the gate voltage changes in the gate finger group, it is possible to sufficiently suppress ringing and oscillation, to realize a stable operation, and, in addition, to secure a high short-circuit resistance.

Note that, in the first to sixth embodiments, description was given using a GaN-based HFET; however, with high-speed turn-ON and turn-OFF times, it is possible to obtain the same effect even for a typical compound semiconductor. In addition, in the first to, sixth embodiments, the gate electrode is formed in a loop shape so as to surround the periphery of the drain electrode; however, the periphery may need not be surrounded in a loop shape.

In addition, a normally-on HFET also has the same effect as a normally-off HFET.

In addition, it is possible to obtain the same effect even when a plurality of the connection points between the gate electrode pad and the gate electrode connecting wire are arranged not only on one side of the rectangular region, that is, not only on one end of the gate finger portion, and it goes without saying that it is possible to obtain the same effect even when the “midpoint” expressed is not the midpoint according to the mathematical strict sense, but the approximate midpoint in the engineering sense.

In addition, the gate electrode connecting wire is not limited to a strict rectangular loop-shape but may be an elliptical shape similar to a rectangle, and, in addition, without being limited to a loop-shape, may be a U-shape or the like as long as there are opposing portions to which both ends of the gate electrode are connected and it is possible to define a substantially rectangular region.

Naturally, the constituent elements described in the first to sixth embodiments and the modification examples may be appropriately combined or may be appropriately selected, replaced, or removed.

The present invention and the embodiments are summarized as follows.

The compound semiconductor field effect transistor of the present invention includes drain electrodes 11 and 131 formed on a semiconductor layer 4 so as to extend in a first direction, source electrodes 12 and 132 formed on the semiconductor layer 4 so as to extend in the first direction and to be separated from the drain electrodes 11 and 131 with an interval determined in advance in a second direction intersecting the first direction, gate electrodes 13 and 133 extending in the first direction and formed between the drain electrodes 11 and 131 and the source electrodes 12 and 132 in plan view, gate electrode connecting wires 15, 85, and 105 that have opposing portions to which both ends of the gate electrodes 13 and 133 in the first direction are connected and that define substantially rectangular regions 20, 30, and 40 having a long side and a short side encompassing all the gate electrodes 13 and 133 in plan view, an insulating layer 8 formed on the semiconductor layer 4 so as to cover the gate electrodes 13 and 133, and gate electrode pads 17, 87, and 107 formed on the insulating layer 8 and connected to the gate electrode connecting wires 15, 85, and 105, in which a plurality of gate fingers 14, 84, 104, 124, and 134 each of which is arranged with the source electrodes 12 and 132 and includes the drain electrodes 11 and 131, the gate electrodes 13 and 133, and a part of the gate electrode connecting wires 15, 85, and 105, gate finger groups 14a, 84a, 84b, 84c, 104a, 104b, 104c, 124a-1, 124b-1, 124c-1, 124a-2, 124b-2, 124c-2, 134a, and 134b including a plurality of the gate fingers 14, 84, 104, 124, and 134 are formed, and connection portions 18, 88, and 108 in the gate electrode connecting wires 15, 85, and 105 which connect the gate electrode connecting wires 15, 85, and 105 and the gate electrode pads 17, 87, and 107 are positioned on the long side of the substantially rectangular regions 20, 30, and 40.

According to the compound semiconductor field effect transistor with the above configuration, since the connection portions 18, 88, and 108 in the gate electrode connecting wires 15, 85, and 105 which connect the gate electrode pads 17, 87, and 107 and the gate electrode connecting wires 15, 85, and 105 are arranged on the long sides of the substantially rectangular regions 20, 30, and 40, the signal delay in the gate finger groups 14a, 84a, 84b, 84c, 104a, 104b, 104c, 124a-1, 124b-1, 124c-1, 124a-2, 124b-2, 124c-2, 134a, and 134b is reduced, it is possible to reduce the gate voltage change, to realize a stable uniform operation, to sufficiently suppress ringing and oscillation, and moreover, to secure a high short-circuit resistance.

In one embodiment, each gate finger group of a plurality of the gate finger groups 14a, 84a, 84b, 84c, 104a, 104b, 104c, 124a-1, 124b-1, 124c-1, 124a-2, 124b-2, 124c-2, 134a, and 134b is surrounded by the gate electrode connecting wires 15, 85, and 105, and, in the gate finger groups 14a, 84a, 84b, 84c, 104a, 104b, 104c, 124a-1, 124b-1, 124c-1, 124a-2, 124b-2, 124c-2, 134a, and 134b, connection portions 18, 88, and 108 in the gate electrode connecting wires 15, 85, and 105 which connect the gate electrode connecting wires 15, 85, and 105 and the gate electrode pads 17, 87, and 107 are positioned at the midpoints on the portions of the long sides in the gate electrode connecting wires 15, 85, and 105 belonging to the gate finger groups 14a, 84a, 84b, 84c, 104a, 104b, 104c, 124a-1, 124b-1, 124c-1, 124a-2, 124b-2, 124c-2, 134a, and 134b.

According to the embodiment described above, each of the plurality of gate finger groups 14a, 84a, 84b, 84c, 104a, 104b, 104c, 124a-1, 124b-1, 124c-1, 124a-2, 124b-2, 124c-2, 134a, and 134b is surrounded by the gate electrode connecting wires 15, 85, and 105, and since the connection portions 18, 88, and 108 in the gate electrode connecting wires 15, 85, and 105 connecting the gate electrode connecting wires 15, 85, and 105 and the gate electrode pads 17, 87, and 107 are positioned at the midpoints of the portion of the long sides in the gate electrode connecting wires 15, 85, and 105 belonging to the gate finger groups 14a, 84a, 84b, 84c, 104a, 104b, 104c, 124a-1, 124b-1, 124c-1, 124a-2, 124b-2, 124c-2, 134a, and 134b, the signal delay is further reduced, it is possible to lower the gate voltage change, to sufficiently suppress ringing and oscillation, to realize a stable uniform operation, and, in addition, to secure a high short-circuit resistance.

In one embodiment, the number of the gate finger groups 104a, 104b, and 104c is 3, the connection portions 108, 108, 108 positioned at the midpoint of the portion of the long side in the gate electrode connecting wire 105 belonging to the adjacent gate finger groups 104a, 104b, and 104c are interconnected with two first gate electrode pad connecting wires 106, 106, and the connection point T1 between the two first gate electrode pad connecting wires 106, 106 is connected to the gate electrode pad 107.

According to the above embodiment, since the connection portions 108, 108, 108 positioned at the midpoint of the portion of the long side in the gate electrode connecting wire 105 belonging to the adjacent gate finger groups 104a, 104b, and 104c are interconnected with two first gate electrode pad connecting wires 106, 106, and the connection point T1 between the two first gate electrode pad connecting wires 106, 106 is connected to the gate electrode pad 107, the signal delay is reduced, it is possible to lower the gate voltage change, to sufficiently suppress ringing and oscillation, to realize a stable uniform operation, and, in addition, to secure a high short-circuit resistance.

In one embodiment, the number of the gate finger groups 104a, 104b, 104c, 124a-1, 124b-1, 124c-1, 124a-2, 124b-2, and 124c-2 in the long side direction is N (N is a natural number, N≧3), the connection portions 108 each positioned at the midpoint of the portion of the long side in the gate electrode connecting wire 105 belonging to the adjacent gate finger groups 104a, 104b, 104c, 124a-1, 124b-1, 124c-1, 124a-2, 124b-2, and 124c-2 are interconnected with (N−1) first gate electrode pad connecting wires 106, here, m=a natural number of 1 to (N−2), a midpoint of the m-th gate electrode pad connecting wire 106 of (N−m) adjacent wires are connected by the (m+1)-th gate electrode pad connecting wire 116 of (N−(m+1)) wires, and a midpoint of the (N−1)-th gate electrode pad connecting wire 116 of one wire is connected to the gate electrode pad 107.

According to the embodiment described above, since the midpoints of the m-th gate electrode pad connecting wire 106 of (N−m) adjacent wires are connected by the m(m+1)-th gate electrode pad connecting wire 116 of (N−(m+1)) wires, and the midpoint of one (N−1)-th gate electrode pad connecting wire 116 is connected to the gate electrode pad 107, the signal delay is further reduced, it is possible to lower the gate voltage change, to sufficiently suppress ringing and oscillation, to realize a stable uniform operation, and, in addition, to secure a high short-circuit resistance.

In one embodiment, the gate electrode pad connecting wires 106 and 116 are parallel to the first direction and a plurality of gate finger groups 124a-1, 124b-1, 124c-1, 124a-2, 124b-2, and 124c-2 are arranged in the second direction.

According to the embodiment described above, since it is possible to make the gate finger groups 124a-1, 124b-1, 124c-1, 124a-2, 124b-2, and 124c-2 into small blocks and to suppress the gate voltage changes in the gate finger groups 124a-1, 124b-1, 124c-1, 124a-2, 124b-2, and 124c-2, it is possible to sufficiently suppress ringing and oscillation, to realize a stable operation, and, in addition, to secure a high short-circuit resistance.

In one embodiment, the length of the gate fingers 14, 84, 104, 124, and 134 extending in the first direction is 2,000 μm or less.

According to the embodiment described above, since the gate finger length is 2,000 μm or less, it is possible to stabilize the operation and to suppress oscillation.

In addition, according to another aspect of the present invention, the compound semiconductor field effect transistor of the present invention includes drain electrodes 11 and 131 formed on the semiconductor layer 4 so as to extend in a first direction, source electrodes 12 and 132 formed on the semiconductor layer 4 so as to extend in the first direction and to be separated from the drain electrodes 11 and 131 with an interval determined in advance in a second direction intersecting the first direction, gate electrodes 13 and 133 extending in the first direction and formed between the drain electrodes 11 and 131 and the source electrodes 12 and 132 in plan view, gate electrode connecting wires 15, 85, and 105 that have opposing portions to which both ends of the gate electrodes 13 and 133 in the first direction are connected and that define substantially rectangular regions 20, 30, and 40 having a long side and a short side encompassing all the gate electrodes 13 and 133 in plan view, an insulating layer 8 formed on the semiconductor layer 4 so as to cover the gate electrodes 13 and 133, and gate electrode pads 17, 87, and 107 formed on the insulating layer 8 and connected to the gate electrode connecting wires 15, 85, and 105, in which a plurality of gate fingers 14, 84, 104, 124, and 134 each of which is arranged with the source electrodes 12 and 132 and includes the drain electrodes 11 and 131, the gate electrodes 13 and 133, and a part of the gate electrode connecting wires 15, 85, and 105, gate finger groups 14a, 84a, 84b, 84c, 104a, 104b, 104c, 124a-1, 124b-1, 124c-1, 124a-2, 124b-2, 124c-2, 134a, and 134b including a plurality of the gate fingers 14, 84, 104, 124, and 134 are formed, and a connection portion 148 in the gate electrode connecting wire 105 which connects the gate electrode connecting wire 105 and the gate electrode pad 107 is positioned on the short side of the substantially rectangular regions 20, 30, 40, each gate finger group of a plurality of gate finger groups 14a, 84a, 84b, 84c, 104a, 104b, 104c, 124a-1, 124b-1, 124c-1, 124a-2, 124b-2, 124c-2, 134a, and 134b is surrounded by the gate electrode connecting wire 105, in each of the gate finger groups 14a, 84a, 84b, 84c, 104a, 104b, 104c, 124a-1, 124b-1, 124c-1, 124a-2, 124b-2, 124c-2, 134a, and 134b, connection portions 148, 148 in the gate electrode connecting wire 105 which connects the gate electrode connecting wire 105 and the gate electrode pad 107 are positioned at the midpoints of the portions of the short sides in the gate electrode connecting wires 105 belonging to the gate finger groups 14a, 84a, 84b, 84c, 104a, 104b, 104c, 124a-1, 124b-1, 124c-1, 124a-2, 124b-2, 124c-2, 134a, and 134b, and the connection portions 148, 148 positioned at the midpoint of the portion of the short side in the gate electrode connecting wire 105 belonging to the adjacent gate finger groups 104a, 104b, 104c, 124a-1, 124b-1, 124c-1, 124a-2, 124b-2, and 124c-2 are interconnected with the gate electrode pad connecting wires 156, and a midpoint of the gate electrode pad connecting wire 156 is directly or indirectly connected to the gate electrode pad 107.

According to the compound semiconductor field effect transistor with the above configuration, even when the ladder wiring is arranged on the short side of the rectangular region, since the connection portions 148, 148 positioned at the midpoint of the portion on the short side in the gate electrode connecting wire 105 are interconnected with the gate electrode pad connecting wire 156 forming the ladder wiring, and the midpoint of the gate electrode pad connecting wire 156 is directly or indirectly connected to the gate electrode pad 107, the signal delay is reduced, it is possible to lower the gate voltage change, to sufficiently suppress ringing and oscillation, to realize a stable uniform operation, and, in addition, to secure a high short-circuit resistance. That is, it is possible to improve the non-uniform operation using the ladder wiring.

In one embodiment, the gate electrode pad connecting wire 156 is parallel to the second direction and a plurality of gate finger groups 124a-1, 124b-1, 124c-1, 124a-2, 124b-2, and 124c-2 are arranged in the first direction.

According to the embodiment described above, since it is possible to make the gate finger groups 124a-1, 124b-1, 124c-1, 124a-2, 124b-2, 124c-2 into small blocks and to suppress the gate voltage changes in the gate finger groups 124a-1, 124b-1, 124c-1, 124a-2, 124b-2, 124c-2, it is possible to sufficiently suppress ringing and oscillation, to realize a stable operation, and, in addition, to secure a high short-circuit resistance.

### REFERENCE NUMERALS

1 Si SUBSTRATE
2 BUFFER LAYER
3 GaN LAYER
4 AlGaN LAYER
5 GaN-BASED LAMINATE
7 PROTECTIVE FILM
8 INSULATING INTERLAYER
9 GATE INSULATING FILM
11, 31, 51, 131 DRAIN ELECTRODE
12, 32, 52, 132 SOURCE ELECTRODE
13, 33, 53, 133 GATE ELECTRODE
14, 54, 64, 124, 134 GATE FINGER
14a, 64a, 64b, 64c, 74a, 74b, 74c, 84a, 84b, 84c, 104a, 104b, 104c, 114a, 114b, 114c, 124a, 124b, 134a, 134b
GATE FINGER GROUP
15, 55, 65, 75, 85, 105 GATE ELECTRODE CONNECTING WIRE
16, 86, 106, 116, 156 GATE ELECTRODE PAD CONNECTING WIRE
17, 87, 107 GATE ELECTRODE PAD
18, 88, 108, 148 CONNECTION PORTION
34 GATE-DRAIN CAPACITANCE
36a, 36b POWER SOURCE
56 GATE-DRAIN CAPACITANCE cgd PER UNIT LENGTH
57 RESISTANCE rg PER UNIT LENGTH
37, 57 GATE TERMINAL
38, 58 DRAIN TERMINAL
39, 59 SOURCE TERMINAL
331 DRAIN RESISTANCE
332 SOURCE RESISTANCE
333, 533 GATE RESISTANCE

1-7. (canceled)

8. A compound semiconductor field effect transistor comprising:
a drain electrode formed on a semiconductor layer so as to extend in a first direction;
a source electrode formed on the semiconductor layer so as to extend in the first direction and to be separated from the drain electrode with an interval determined in advance in a second direction intersecting the first direction;
a gate electrode extending in the first direction and formed between the drain electrode and the source electrode in plan view;
a gate electrode connecting wire that has opposing portions to which both ends of the gate electrode in the first direction are connected and that defines a substantially rectangular region having a long side and a short side encompassing all the gate electrode in plan view;
an insulating layer formed on the semiconductor layer so as to cover the gate electrode; and
a gate electrode pad formed on the insulating layer and connected to the gate electrode connecting wire,
wherein a plurality of gate fingers each of which is arranged with the source electrode and includes the drain electrode, the gate electrode, and a part of the gate electrode connecting wire,
at least one gate finger group including a plurality of the gate fingers is formed,
a connection portion in the gate electrode connecting wire which connects the gate electrode connecting wire and the gate electrode pad is positioned on the long side of the substantially rectangular region,
each gate finger group of a plurality of the gate finger groups is surrounded by the gate electrode connecting wire, and
in each of the gate finger groups, a connection portion in the gate electrode connecting wire which connects the gate electrode connecting wire and the gate electrode pad is positioned at a midpoint of a portion of the long side in the gate electrode connecting wire belonging to the gate finger group.

9. The compound semiconductor field effect transistor according to claim 8,
wherein the number of the gate finger groups in the long side direction is N (N is a natural number and N≧3),
connection portions each positioned at a midpoint of a portion of the long side in the gate electrode connecting wire belonging to adjacent gate finger groups are interconnected with (N−1) first gate electrode pad connecting wires,
here, m=a natural number of 1 to (N−2),
midpoints of an m-th gate electrode pad connecting wire of (N−m) adjacent wires are connected by an (m+1)-th gate electrode pad connecting wire of (N−(m+1)) wires, and
a midpoint of one (N−1)-th gate electrode pad connecting wire is connected to the gate electrode pad.

10. The compound semiconductor field effect transistor according to claim 9,
wherein the gate electrode pad connecting wire is parallel to the first direction, and
a plurality of gate finger groups are arranged in the second direction.

11. The compound semiconductor field effect transistor according to claim 8,
wherein a length of the gate finger extending in the first direction is 2,000 μm or less.

12. A compound semiconductor field effect transistor comprising:
a drain electrode formed on a semiconductor layer so as to extend in a first direction;
a source electrode formed on the semiconductor layer so as to extend in the first direction and to be separated from the drain electrode with an interval determined in advance in a second direction intersecting the first direction;
a gate electrode extending in the first direction and formed between the drain electrode and the source electrode in plan view;
a gate electrode connecting wire that has opposing portions to which both ends of the gate electrode in the first direction are connected and that defines a substantially rectangular region having a long side and a short side encompassing all the gate electrode in plan view;
an insulating layer formed on the semiconductor layer so as to cover the gate electrode; and
a gate electrode pad formed on the insulating layer and connected to the gate electrode connecting wire,
wherein a plurality of gate fingers each of which is arranged with the source electrode and includes the drain electrode, the gate electrode, and a part of the gate electrode connecting wire,
at least one gate finger group including a plurality of the gate fingers is formed,
a connection portion in the gate electrode connecting wire which connects the gate electrode connecting wire and the gate electrode pad is positioned on the short side of the substantially rectangular region,
each gate finger group of a plurality of the gate finger groups is surrounded by the gate electrode connecting wire,
in each of the gate finger groups, a connection portion in the gate electrode connecting wire which connects the gate electrode connecting wire and the gate electrode pad is positioned at a midpoint of a portion of the short side in the gate electrode connecting wire belonging to the gate finger group,
connection portions each positioned at a midpoint of a portion of the short side in the gate electrode connecting wires belonging to adjacent gate finger groups are interconnected with a gate electrode pad connecting wire, and
a midpoint of the gate electrode pad connecting wire is directly or indirectly connected to the gate electrode pad.

13. The compound semiconductor field effect transistor according to claim 12,
wherein the gate electrode pad connecting wire is parallel to the second direction, and
a plurality of gate finger groups are arranged in the first direction.
